(19) United States
(12) Patent Application Publication
(10) Pub. No.: US 2005/0088895 A1
(43) Pub. Date: Apr. 28, 2005

(54) DRAM cell array having vertical memory cells and methods for fabricating a DRAM cell array and a DRAM

(75) Inventors: Dirk Manger, Dresden (DE); Till Schloesser, Dresden (DE); Rolf Weis, Dresden (DE); Bernd Goebel, Dresden (DE); Wolfgang Mueller, Radebeul (DE); Joachim Nuetzel, Dresden (DE); Klaus Muemmler, Dresden (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(73) Assignee: Infineon Technologies AG

(21) Appl. No.: 10/897,687

(22) Filed: Jul. 23, 2004

(30) Foreign Application Priority Data
Jul. 25, 2003 (DE) 103 34 113.7
Jul. 25, 2003 (DE) 103 34 114.5
May 27, 2004 (DE) 10 2004 026 000.1

(51) Int. Cl. G11C 11/34

(52) U.S. Cl. 365/222

(57) ABSTRACT

Memory cells having a cell capacitor and a cell transistor, which are arranged in a vertical cell structure, are provided in the cell array of a DRAM. By means of a deep implantation or a shallow implantation with subsequent epitaxial growth of silicon, a buried source/drain layer is formed, from which lower source/drain regions of the cell transistors emerge. The upper edge of the buried source/drain layer can be aligned with respect to a lower edge of a gate electrode of the cell transistor, which consequently results in a reduction of a gate/drain capacitance and also a leakage current between the gate electrode and the lower source/drain region. A gate conductor layer structure is applied and there are formed, from the gate conductor layer structure, in a controlled transistor array, gate electrode structures of control transistors and, in the cell array, a body connection structure for the connection of body regions of the cell transistors.

### CROSS-REFERENCE TO RELATED APPLICATIONS

This Utility Patent Application claims priority to German Patent Application Nos. DE 103 34 113.7, filed on Jul. 25, 2003; DE 103 34 114.5, filed on Jul. 25, 2003; and DE 10 2004 026 000.1 filed on May 27, 2004, which are all incorporated herein by reference.

This Patent Application is also related to Utility Patent Application Ser. No. ______, filed on even date herewith, entitled “DRAM CELL ARRAY AND MEMORY CELL ARRANGEMENT HAVING VERTICAL MEMORY CELLS AND METHODS FOR FABRICATING THE SAME,” having Docket No. I433.113.101 and is commonly assigned to the same assignee as the present invention, and which is herein incorporated by reference.

### BACKGROUND

The invention relates to a cell array having memory cells arranged in a semiconductor substrate to form cell rows and each having a cell capacitor for storing an electrical charge that characterizes a data content of the memory cell and a cell transistor for selection of the memory cell, in which word line trenches are arranged between the cell rows, the cell capacitor is provided in a lower region of a hole trench introduced from a substrate surface of the semiconductor substrate with an inner electrode arranged in the hole trench, and the cell transistor is formed along an upper region of the hole trench in the semiconductor substrate and has an upper source/drain region, which adjoins the substrate surface and is near the surface, a lower source/drain region, which is connected to the inner electrode of the cell capacitor, and a channel region, which separates the two source/drain regions from one another and is insulated by a gate dielectric from a gate electrode provided in the word line trenches.

The invention furthermore relates to methods for fabricating a cell array and a semiconductor memory device.

Memory cells of dynamic random access memories in each case comprise a cell capacitor and a cell transistor. An electrical charge is stored on a storage electrode of the cell capacitor during operation of the memory cell, the value of said charge corresponding to a respective binary data content of the memory cell. Via the cell transistor, the storage electrode is connected to a data line (also called bit line hereinafter) for the purpose of changing or reading out the data content. The cell transistor is a field-effect transistor, the gate electrode of which is connected to a word line by means of which the memory cell is addressed. A first source/drain region of the cell transistor is connected to the bit line and a second source/drain region is connected to the storage electrode of the cell capacitor. By means of a suitable potential at the gate electrode, a conductive channel is formed in a channel or body region between the two source/drain regions, via which channel the storage electrode is connected to the bit line when writing to and reading from the memory cell.

The cell capacitors are provided above or below a transistor plane formed by the cell transistors. In the case of memory cells having cell capacitors formed as hole trench capacitors or trench capacitors, the cell capacitors are formed below the transistor plane in a manner oriented to hole trenches introduced into a semiconductor substrate. The storage electrode is usually provided as an inner electrode within the hole trench and insulated by a capacitor dielectric from an outer electrode formed as a doped region in the semiconductor substrate enveloping the hole trench.

In the case of memory cells embodied in a technology with a minimum feature size of greater than 110 nm, the cell transistors are usually shaped in planar fashion in a manner oriented to a substrate surface of the semiconductor substrate (PTC, planar transistor cell). The source/drain regions of planar cell transistors are provided next to one another below the substrate surface in a manner separated from one another by the channel region. The conductive channel between the two source/drain regions, which can be controlled by the potential at the gate electrode, is essentially formed parallel to the substrate surface.

As a result of progressive reduction of the minimum feature size, it is generally endeavored to increase the performance of DRAMs and to reduce the fabrication costs per memory cell. In the case of memory cells having planar cell transistors, smaller feature sizes lead to shorter channel lengths of the channel formed between the two source/drain regions. In the case of minimum feature sizes of less than 110 nm, a shortening of the channel length corresponding to a miniaturization of the minimum feature size leads to more than proportional difficulties in connection with a lower memory voltage that is then necessary and in the realization of a doping profile of the cell transistor.

Therefore, it is known to orient the cell transistors vertically with respect to the substrate surface in order to decouple the channel length of the cell transistors from the minimum horizontal feature size which can be achieved by the lithographic method respectively used. The two source/drain regions and the channel region lying in between are arranged one above the other. In a vertical memory cell or a memory cell having a vertical cell transistor (VTC, vertical transistor cell), the channel is principally formed in a direction perpendicular to the transistor plane.

By way of example, DE 197 18 721 A1 (Roesner et al.) describes a vertical memory cell structure in which the cell or selection transistor is composed of two twin transistors that are opposite one another at the hole trench and are connected to the inner electrode by a symmetrical contact window. If the memory cells are arranged to form memory cell rows insulated from one another by isolation trenches, then it is necessary to effect a double contact-connection of the mutually insulated upper source/drain regions of the two twin transistors to the data line. The double contact-connection as well as the required distance between the twin transistors of memory cells that are adjacent in a memory cell row disadvantageously require a greater distance between the memory cells than would be necessary due to the dictates of lithography. Recent concepts therefore provide for forming the selection transistor only at one side of the hole trench.

What is disadvantageous about the vertical memory cell structure described is, in particular, the fact that a storage capacitor formed in a hole trench is in each case arranged between two selection transistors but is only assigned in each case to one of the adjoining selection transistors. In other words, the storage capacitor has to be connected on one side to one of the two spatially adjoining selection transistors and be insulated from the respective other selection transistor which is opposite to the assigned selection transistor in the memory cell row at the hole trench and is assigned to the adjacent memory cell. The requisite processing of a single sided conductor junction between the inner electrode and the lower source/drain region of the assigned selection transistor (single sided buried strap) requires a complex processing, as is known for instance from U.S. Pat. No. 6,426,526 (Divakaruni et al.). In this case, an etching resistance of an auxiliary layer that is provided in the hole trench above the inner electrode is altered asymmetrically essentially by means of an oblique implantation and then the auxiliary layer is subjected to an etching process that acts selectively with respect to this change. The single sided forming of a contact window between the inner electrode of the storage capacitor and the lower source/drain region of the assigned selection transistor comprises a process module with a plurality of complex process steps.

Other concepts for vertical memory cells provide for forming the gate electrodes exclusively in the upper region of the hole trenches and connecting them to one another by means of overlying address lines. In such memory cell structures, too, the packing density of the memory cells is restricted by the required distance between the selection transistors of adjacent memory cells.

Usually, for forming the first source/drain region connected to the bit line, the semiconductor substrate is doped in a region near the surface below the substrate surface by means of an ion implantation that is unmasked in the cell array. The second source/drain region connected to the storage electrode of the cell capacitor is formed by outdiffusion of a dopant from a material introduced into the hole trench at least temporarily through a contact window (buried strap window) in the wall of the hole trench in a section of the semiconductor substrate adjoining the contact window. The buried strap diffusion region has a high dopant concentration in the region of the contact window, said dopant concentration decreasing in the vertical and horizontal directions. If the distance between two memory cells that are adjacent in a cell row is larger than the buried strap diffusion region including a space charge zone formed in their boundary region, then the channel region is connected to a connection structure which, below the buried strap diffusion regions, connects the channel regions of cell transistors arranged to form a cell array to one another with high impedance. A high-impedance connection with a resistivity resulting in the order of magnitude of the intrinsic conduction of the material of the semiconductor substrate generally suffices for avoiding floating body effects during operation of the memory cell. The floating body effect means for instance that charge carriers are accumulated in the channel region and a leakage current that discharges the storage electrode is established via a parasitic bipolar transistor structure that is consequently built up.

The gate electrode is provided in a manner corresponding to a region of the hole trench above the cell capacitor in word line trenches between the memory cells arranged in rows (double gate transistor) or both in the word line trenches and in the hole trench (surrounded gate transistor) and is insulated from the channel region by a gate dielectric.

An overlap between the gate electrode and a weakly doped section of the lower source/drain region is advantageous. By contrast, an overlap between the gate electrode and heavily doped sections of the lower source/drain region results in an increased gate/drain capacitance C_{GD}, which reduces a switching speed of the cell transistor and thus increases an access time of the DRAM. Moreover, a leakage current path between the buried strap diffusion region and the gate electrode contributes a significant proportion of the total leakage current of the memory cell. A high leakage current disadvantageously increases the access time and the power consumption of the DRAM by virtue of the higher frequency of the refresh cycles that is then required. Furthermore, a high doping in the overlap region results in high local field strengths in the region of the gate dielectric, which impair the reliability thereof.

### SUMMARY

One embodiment of the invention provides a cell array and a semiconductor memory device having vertical DRAM memory cells with short access times and a low power consumption. Furthermore, a method is specified for fabricating a cell array and a method for fabricating a DRAM with a short access time and a low power consumption.

One embodiment of the present invention provides a vertical memory cell structure whose fabrication does not require a single sided formation of a contact window between an inner electrode of a storage capacitor and a lower source/drain region of a selection transistor and which at the same time permits a packing density of the memory cells which is limited essentially by the lithography technique used. Furthermore a method is specified for fabricating such a vertical memory cell structure.

The cell array comprises memory cells arranged in a semiconductor substrate to form cell rows and each having a cell capacitor for storing an electrical charge that characterizes a data content of the memory cell and a cell transistor for selection of the memory cell. Word line trenches are provided between the cell rows. The cell capacitor is formed in a lower region of a hole trench introduced from a substrate surface of the semiconductor substrate and has an inner electrode arranged within the hole trench. A semiconductor body of the cell transistor, which comprises an upper and a lower source/drain region and also a channel region, is formed in the semiconductor substrate in a manner oriented to an upper region of the hole trench. The upper source/drain region of the cell transistor adjoins the substrate surface in a section of the semiconductor substrate near the surface. The lower source/drain region is electrically conductively connected to the inner electrode of the cell capacitor. The two source/drain regions are formed as doped regions of a first conductivity type and are separated from one another by the channel region. The channel region is not doped or has a weak doping of a second conductivity type opposite to the first conductivity type. A gate dielectric insulates the channel region from a gate electrode provided in the word line trenches.

According to one embodiment of the invention, the lower source/drain regions of the cell transistors in each case comprise sections of a buried source/drain layer perforated by the hole trenches and the word line trenches. A horizontal doping profile and a vertical doping profile of the lower source/drain region are thus advantageously decoupled from one another. In the cell array, the source/drain layer has a doping profile that is location-independent in the horizontal direction.

In conventional vertical cell transistors, the lower source/drain region is formed solely by outdiffusion of a dopant from the interior of the hole trench through a contact window in an insulator structure, which insulates the inner electrode from the semiconductor substrate enveloping the hole trench, in a section of the semiconductor substrate adjoining the contact window. The doping profile of the buried strap diffusion region is dependent in the vertical and horizontal directions on a thermal budget to which the cell structure is exposed in the course of fabrication of a DRAM. The spatial position and the extent of the lower source/drain region are determined by the form and position of the contact window, by the distribution of the dopant in the starting material, and by the thermal budget. In particular, the doping profile in the vertical direction and the doping profile in the horizontal direction are linked to one another. The extent of a section in which the lower source/drain region has a relatively heavy doping in the vertical direction is dependent on the tolerances of a multiplicity of process steps for instance for forming the contact window. Consequently, an overlap region between the heavily doped section of the lower source/drain region and the gate electrode arranged in the word line trenches results, which disadvantageously leads to a longer access time and/or to a higher leakage current.

The source/drain layer according to one embodiment of the invention advantageously decouples the geometry of the lower source/drain region from the geometry of the buried strap diffusion region. The function of the buried strap diffusion region is essentially limited to producing a low-impedance connection between the inner electrode and a section of the source/drain layer assigned to the respective memory cell. The functionality of the lower source/drain region is principally determined by the respective section of the source/drain layer. The distances between upper edge and lower edge of the lower source/drain regions of the cell transistors arranged in the cell array with respect to the substrate surface have only small deviations from one another owing to the formation as sections of the source/drain layer over the entire cell array.

The channel regions and the upper source/drain regions of the cell transistors are formed in an epitaxially grown layer of the semiconductor substrate. This results, over the entire cell array, in a uniform distance between the upper edge of the lower source/drain region and the substrate surface and thus between the lower source/drain region and a lower edge of the gate electrode.

In one embodiment, at least one upper section of the buried source/drain layer is formed in the epitaxially grown layer of the semiconductor substrate. A doping profile that is independent of diffusion processes to a greater degree and can be better controlled then results in the transition region between the buried source/drain layer and the channel region and thus in the region of overlap with the gate electrode.

The memory cells have a buried strap diffusion region formed as a doped region of the first conductivity type in the semiconductor substrate. The buried strap diffusion region adjoins the inner electrode in the region of a contact window and overlaps or penetrates the section of the buried source/drain layer assigned to the respective memory cell. The buried strap diffusion region advantageously reduces an electrical resistance between the inner electrode of the cell capacitor and the lower source/drain region of the cell transistor.

The buried strap diffusion region is formed such that the upper edge of the lower source/drain region is determined by the upper edge of the buried source/drain layer.

If the gate electrodes of memory cells that are adjacent within a cell row are connected to form word lines running along sidewalls of the word line trenches, then it is advantageous that, correspondingly, a lower edge of the word lines is provided above the upper edge of the buried strap diffusion region and below the upper edge of the buried source/drain layer. This reduces a proportion of a leakage current path between the lower source/drain region and the word line, or the gate electrode, in the total leakage current of the memory cell since the magnitude of the proportion is proportional to a dopant concentration in the section of the lower source/drain region which overlaps the gate electrode.

The channel region is undoped or has a counterdoping of the second conductivity type.

The formation of the lower source/drain regions as sections of a layer that is perforated merely by the hole trenches and the word line trenches means that the channel regions of the cell transistors can no longer readily be electrically connected to a connection structure that is to be provided below the lower source/drain regions. In order to avoid a patterning of the lower source/drain layer, it is advantageous if the channel regions adjoin the substrate surface in sections and are connected to a conductive connection structure formed above the substrate surface.

A semiconductor memory device according to one embodiment of the invention has a cell array of memory cells having cell transistors for addressing the memory cells.

A first and a second source/drain region of a cell transistor are in each case formed in a semiconductor substrate and spaced apart from one another by a body region adjoining a substrate surface of the semiconductor substrate. Outside the cell array, control transistors for controlling the cell array are formed in a control transistor array, gate electrode structures of the control transistors being provided above the substrate surface.

According to one embodiment the invention, a body connection structure which bears on the substrate surface is provided in the cell array and is electrically conductively connected to the channel or body regions of the cell transistors that adjoin the substrate surface in sections. In the cell array, the body connection structure may be provided with the same layer thickness as the gate electrode structures of control transistors in the control transistor array. The uniform layer thickness or step height advantageously obviates transition regions that are otherwise necessary between the cell array and the control transistor array.

The memory cells of the semiconductor memory device are case formed in the region of a hole trench introduced into a semiconductor substrate from a substrate surface. For this purpose, a cell capacitor for storing an electrical charge that characterizes a data content of the memory cell is formed in a lower region of the hole trench. The electrical charge is read out or brought to an inner electrode provided within the hole trench via a source/drain path between the two source/drain regions of the respective cell transistor.

The cell transistor has a source/drain region which adjoins the substrate surface and is connected to a bit line and is near the surface, as first source/drain region. A lower source/drain region is connected as second source/drain region to the inner electrode of the cell capacitor. The two source/drain regions are separated from one another by the channel region that adjoins the substrate surface in sections.

The channel region is insulated by a gate dielectric from a gate electrode connected to a word line. In the channel region, a channel that temporarily connects the two source/drain regions to one another is controlled by a potential at the gate electrode. The word lines are arranged in rows in word line trenches below the substrate surface. The bit lines are provided above the substrate surface and run parallel to the substrate surface and perpendicular to the word lines. The channel regions are connected to one another above the substrate surface.

The body connection structure may be formed in a strip-like manner in the form of body connection lines that are parallel to one another, a body connection line in each case connecting the body or channel regions of cell transistors arranged in a cell row. The body connection lines may be arranged orthogonally to the cell rows and in each case connect the body or channel regions of cell transistors that are adjacent perpendicularly to the cell rows, or run obliquely with respect to the cell rows.

In one embodiment, the body connection structure is formed as a body connection plate made of a conductive material which covers the cell array, bears on the substrate surface and is perforated by electrically insulated contact holes for connection of the upper source/drain regions to the bit lines.

In the case of a known concept for a connection of the channel regions from “above”, that is to say past the upper source/drain regions, the word lines are provided above the substrate surface. Body connection lines which connect the channel regions of cell transistors to one another in columns perpendicularly to the cell row are then formed in a self-aligned manner with respect to the word lines running parallel.

The body connection structure is provided at least with a partial layer made of polysilicon having a doping of the second conductivity type, which is opposite to the first conductivity type of the source/drain regions. This advantageously results in the possibility of forming, by outdiffusion from the body connection structure, in each case a body contact diffusion region as a doped region of the second conductivity type in a section of the channel region adjoining the substrate surface.

The body contact diffusion region enables or improves a transporting away of charge carriers from the channel region.

A nitrided boundary layer is provided between the channel region and the body connection structure, in order to avoid a disruption of the crystal structure of the semiconductor substrate due to ingrowth of grain boundaries from the polysilicon of the body connection structure.

The regions of the first conductivity type are preferably n-doped. The cell transistors are then n-channel field-effect transistors, which are simpler to fabricate compared with p-channel field-effect transistors with comparable functionality.

The body connection structure in the cell array and the gate electrode structures of the control transistors in the control transistor array emerge from the same layer structure. The photolithographic method for imaging the gate electrode structures and the body connection structure onto the surface of the layer structure requires only a single mask and a single exposure process, thereby obviating the difficulty of aligning two independent masks relative to one another. The manufacturing outlay is reduced. The process steps for forming the gate electrode structures and for forming the body connection structure are effected simultaneously. The common process window is advantageously larger than each individual process window during a progressive processing, since otherwise, for instance in the case of an annealing step provided for the subsequently processed structure, the effect of said step on the previously processed structure has to be taken into account.

Furthermore, the same layer thickness or step height advantageously results for the body connection structure and also the gate electrode structures.

In accordance with the method according to one embodiment of the invention for fabricating a cell array having memory cells arranged in memory cell rows in a semiconductor substrate, the memory cells are provided with in each case a cell capacitor for storing an electrical charge that characterizes a data content of the memory cell and a cell transistor for selection of the memory cell. For this purpose, firstly hole trenches are introduced into the semiconductor substrate from a substrate surface. An inner electrode of the cell capacitor is in each case provided in a lower section of the hole trenches. An outer electrode of the cell capacitor is formed in the semiconductor substrate enveloping the hole trench in the lower section. A capacitor dielectric is provided between the inner electrode and the outer electrode. The cell transistor is in each case provided in a manner oriented to an upper section of the hole trench in that a lower source/drain region adjoining the inner electrode, an upper source/drain region adjoining the substrate surface and a channel region separating the source/drain regions from one another are formed in each case in the semiconductor substrate adjoining the hole trench. The channel region is insulated by a gate dielectric from a gate electrode which is formed at least partially as a section of a word line provided in word line trenches introduced between the cell rows. The upper source/drain region is connected to a bit line.

According to one embodiment of the invention, the lower source/drain region is at least partially formed as a buried source/drain layer perforated by the hole trenches and the word line trenches.

In a first embodiment of the method according to the invention, the buried source/drain layer is formed by a deep ion implantation with a dopant of a first conductivity type into the semiconductor substrate.

An ion implantation with a dopant of a second conductivity type opposite to the first conductivity type is performed in a layer forming the channel regions in the cell array, in order to define the doping profile in a transition region between the lower source/drain region and the channel region.

According to a second embodiment of the method according to the invention, in a first step, a shallow ion implantation is performed in the region of the cell array. In a second step, at least the sections of the semiconductor substrate that are to be provided above the buried source/drain layer are grown epitaxially. This advantageously results in a well-alignable upper edge of the buried source/drain layer in the cell array.

The cell capacitor is provided with a contact window, in the region of which the inner electrode adjoins the semiconductor substrate. In an advantageous manner, a buried strap diffusion region which adjoins the inner electrode and at least partially overlaps the buried source/drain layer and penetrates this is formed by outdiffusion of a dopant of the first conductivity type from the interior of the hole trench through the contact window in the semiconductor substrate. The buried strap diffusion region reduces a contact resistance between the inner electrode and the lower source/drain region. In this case, the outdiffusion is controlled such that the properties of the lower source/drain region, apart from the contact resistance with respect to the inner electrode, are determined by the buried source/drain layer, which can be produced more variably and more precisely in comparison with the outdiffusion.

The design of the lower source/drain regions as sections of a source/drain layer extending through the cell array makes it more difficult to make contact with the channel region proceeding from a connection structure provided below the lower source/drain regions. A method for forming body connection lines above the substrate surface is furthermore known, in which only the channel regions of cell transistors that are adjacent on a line transversely with respect to the cell row are connected to one another. Since a charge carrier transport is effected via the comparatively high-impedance body connection lines, the compensating current accumulates within the body connection line, so that differing conditions with regard to a charge in the channel region result for the memory cells connected by the body connection lines.

The buried source/drain layer according to one embodiment of the invention therefore leads to a method according to the invention for fabricating a semiconductor memory device having memory cells each having a cell capacitor for storing electrical charge in accordance with a data content of the memory cell and a cell transistor for addressing the memory cell in a semiconductor substrate in which, in addition to the upper source/drain regions, the channel regions are also connected above a substrate surface of the semiconductor substrate.

For this purpose, hole trenches arranged to form cell rows from a substrate surface are introduced into the semiconductor substrate, the cell capacitor being formed in a manner oriented to a lower section of the hole trench and the cell transistor being formed in a manner oriented to an upper section of the hole trench. A semiconductor body of the cell transistor comprising an upper and a lower source/drain region and also a channel region is formed in the semiconductor substrate, the lower source/drain region being connected to one of the electrodes of the cell capacitor. The upper source/drain region is provided in a manner adjoining the substrate surface. The channel region separating the two source/drain regions likewise adjoins the substrate surface in sections. The upper source/drain region is connected to a bit line and the channel region is connected to a substrate connection. Word lines for controlling a potential at the gate electrodes are arranged below the substrate surface in word line trenches introduced from the substrate surface between cell rows formed by the memory cells.

According to one embodiment of the invention, a body connection plate is applied to the substrate surface prior to the formation of the upper source/drain regions in the region of the cell array. Contact holes are introduced into the body connection plate and are electrically insulated from the body connection plate. By means of an implantation with a dopant corresponding to the conductivity type of the upper source/drain regions, the upper source/drain regions are formed as doped regions through the contact holes and in a manner masked by the body connection plate in sections of the semiconductor substrate adjoining below the contact holes. The upper source/drain regions are thus advantageously formed in a self-aligned manner with respect to the contact holes which are provided for connecting the upper source/drain regions to the bit line. Only a relatively noncritical patterning of the bit lines with respect to the contact holes is effected in a bit line plane adjoining above the body connection plate. The connection of the channel regions does not require an additional critical lithographic mask.

The body connection plate is provided from polysilicon. It is then advantageous if the semiconductor substrate is nitrided prior to the application of the body connection plate in the cell array in the region of the substrate surface, in order to avoid a disruption of the crystal lattice of the semiconductor substrate due to ingrowth of grain boundaries of the polysilicon.

Polysilicon doped by the second conduction type is provided as the material of the body connection plate and a body contact diffusion region is formed by outdiffusion from the doped polysilicon in the section of the channel region that adjoins the body connection plate below the substrate surface, which body contact diffusion region reduces a contact resistance between the channel region and the body connection plate.

Linking the fabrication of the body connection plate with the fabrication of gate electrode structures of planar control transistors formed outside the cell array results in a further method according to the invention for fabricating a semiconductor memory device, which method is independent of the embodiment of the cell array and a patterning of the body connection plate.

According to one method, in an initially customary manner, cell transistors having in each case a body or channel region, which is formed in a semiconductor substrate and spaces apart a first and a second source/drain region from one another and adjoins a substrate surface, are formed in a cell array of the semiconductor memory device. A gate dielectric layer is provided on the substrate surface of the semiconductor substrate. A monolayer or multilayer gate conductor layer structure is applied to the gate dielectric layer. Gate electrode structures of control transistors are formed in a control transistor array of the semiconductor memory device by patterning the gate conductor layer structure.

According to one embodiment of the invention, the gate dielectric layer is firstly provided over the whole area both in the control transistor array and in the cell array. The gate dielectric layer in the cell array is subjected to a treatment that reduces the electrical resistivity. In this case the treatment may be performed directly after the deposition of the gate dielectric layer or after the application of a part or the complete gate conductor layer structure.

The method according to one embodiment of the invention advantageously makes it possible to develop gate electrode structures from the gate conductor layer structure in the control transistor array and a body connection structure in the cell array, the gate electrode structures in each case being insulated from the semiconductor substrate by a gate dielectric that has emerged from the gate dielectric layer, and the body connection structure electrically conductively adjoining the semiconductor substrate in the region of the body regions of the cell transistors via a modified gate dielectric layer.

The gate conductor layer structure is applied to the gate dielectric layer over the whole area and a body connection structure that makes contact with the body regions is formed from the gate conductor layer structure in the cell array. The method according to the invention advantageously makes it possible to form the body connection structure and the gate electrode structures in the course of the same patterning step.

According to a first embodiment of the method according to the invention, the electrical resistance of the gate dielectric layer in the cell array is reduced by implantation with a dopant, the dielectric material of the gate dielectric layer being at least partly converted into a comparatively low-impedance material. The implantation may be performed prior to the deposition of the gate conductor layer structure or after the deposition at least of partial layers of the gate conductor layer structure or prior to the application of the first metal-containing partial layer of the gate conductor layer structure.

The dopant is chosen from a material group which preferably comprises the elements nitrogen, boron, germanium and indium.

According to further embodiments of the method according to the invention, on the one hand, the growth of the gate dielectric layer in the cell array is suppressed or delayed by means of a pretreatment of the semiconductor substrate, for instance by means of a nitridation, and, on the other hand, a grown gate dielectric layer is caused to recede or removed in the cell array by means of a wet etching process.

The electrical resistance of the gate dielectric layer in the cell array is further preferably reduced by application of an electrical potential between the body connection structure and the semiconductor substrate. In this case, the potential is chosen to be high enough to destroy the gate dielectric layer to an extent such that the electrical resistance between the body connection structure and the semiconductor substrate becomes sufficiently low.

The described methods for reducing the electrical resistance of the gate dielectric layer are in part also possible in combinations.

The method according to the invention is independent of the processing of the gate electrode structures of the control transistors. In particular, it can also be combined with “dual work function” processes in the control transistor array.

For this purpose, according to a embodiment of the method according to the invention, the formation of the gate conductor layer structure comprises the deposition of a partial layer made of intrinsically conducting polysilicon. In addition, the gate conductor layer structure may be provided with further partial layers made of metals and metal compounds.

In the course of a “dual work function” process, the partial layer made of intrinsically conducting polysilicon in the cell array, and also the source/drain regions and the gate electrode structures of control transistors formed as p-channel field-effect transistors are doped with a dopant of the p-conductivity type in the same doping step.

According to another embodiment, the gate conductor layer structure is deposited as a layer made of doped polysilicon.

The processing of the body connection structure is effected analogously to the processing of the gate electrode structures of p-channel field-effect transistors in the control transistor array, thereby further reducing an additional outlay for the formation of the body connection structure.

According to one embodiment, the semiconductor substrate is superficially nitrided prior to the provision of the gate dielectric layer.

The method according to one embodiment of the invention is advantageous particularly when the gate dielectric layer is provided with a layer thickness of a maximum of 2.5 nanometers, since the conversion of the gate dielectric layer in the cell array into a modified, comparatively low-impedance layer can then be effected with a low outlay.

In connection with a method for fabricating a semiconductor memory device, for instance a DRAM, having a cell array having memory cells for storing data and a control transistor region for controlling the cell array, in which p-channel field-effect transistors with a gate electrode made of polysilicon are provided in the control transistor region, a particular advantage is afforded according to the invention when the cell array is formed in accordance with the method already described and, in this case, the application of the body connection plate in the cell array is effected in one process together with an application of the gate electrode material of the p-channel field-effect transistors in the control transistor region. The application of the body connection plate does not then require an additional process step.

The memory cell arrangement according to the invention has, in an initially known manner, a storage capacitor formed in each case in a semiconductor substrate and serving for storing a charge that is characteristic of respective data content, and also a selection transistor for addressing the storage capacitor. A plurality of the memory cells are in each case arranged along a row axis to form memory cell rows. The storage capacitors are in each case formed in the region of a hole trench introduced into the semiconductor substrate from a substrate surface below a contact lower edge. Below the contact lower edge, the hole trenches are filled with a conductive electrode material that in each case forms inner electrodes. The inner electrodes are insulated by a capacitor dielectric from respectively assigned outer electrodes formed as doped regions in the semiconductor substrate. Above the contact lower edge, contact structures made of the conductive electrode material which adjoin the inner electrodes in each case are provided in the hole trenches. Contact areas are formed between the contact structures and a lower source/drain region of a respectively assigned selection transistor, said lower source/drain region in each case being opposite one of the contact structures in the semiconductor substrate. The lower source/drain region, an upper source/drain region and also a channel region—arranged between the two source/drain regions—of the selection transistor are provided in the semiconductor substrate between the substrate surface and the contact structure. Gate conductor structures of selection transistors arranged in the same memory cell row in each case are connected to one another by address lines provided below the substrate surface.

The invention now provides for the lower source/drain region of a selection transistor in each case to have source/drain sections which are contiguous among one another and are opposite to one another on the row axis at the hole trench assigned to the selection transistor.

In comparison with memory cell arrangements having the same packing density, in a particularly advantageous manner, this obviates the need to connect the contact structure in each case only on one side and to insulate it from the semiconductor substrate on a side opposite to the connection. A process module for a single sided forming of a contact window between the inner electrode and the lower source/drain region is obviated. The selection transistors are in each case shaped around the hole trench in which the storage capacitor assigned to the selection transistor is formed.

Consequently, in particular the contact structures are in each case formed symmetrically with respect to a plane of symmetry which runs through a central axis of the respective hole trench and orthogonally to the row axis. The contact area between in each case an inner electrode and a lower source/drain region then has contact sections symmetrically opposite to one another on the row axis at the respective hole trench.

A conductive channel that can be controlled by a potential at the gate conductor structure of the selection transistor is formed essentially vertically with respect to the substrate surface in the channel region of the selection transistor that is arranged between the lower source/drain region and an upper source/drain region. A channel length (device length) of the channel is independent of planar dimensions of the memory cell.

The contiguous lower source/drain region envelops at least 50% of the respectively assigned hole trench.

The lower source/drain regions completely encompass the respectively assigned hole trench, thereby forming a channel with a maximum channel width relative to a diameter of the hole trench.

The arrangement or formation of the lower source/drain regions in relation to the respectively assigned inner electrode is important. The channel regions are provided in each case in a manner adjoining the lower source/drain regions in the vertical direction. Equally, the upper source/drain regions are arranged in each case in a manner adjoining the channel regions in sections in the vertical direction. This results in a contiguous channel region in each case and a contiguous upper source/drain region in each case.

The upper source/drain region, the channel region and the lower source/drain region of the selection transistors are formed together in each case in a substrate sleeve that extends from the substrate surface at least as far as the contact lower edge and envelops the hole trench. Such a substrate sleeve may advantageously be fabricated in the course of a single etching step.

The gate conductor structures are in each case arranged along an essentially in the region of the channel region at a section of an outer wall of the substrate sleeve and envelop the latter in each case completely. By virtue of such an arrangement of the gate conductor structure, the respectively enclosed channel region is advantageously largely shielded against external stray fields.

The gate conductor structures are essentially arranged between a lower edge of the upper source/drain region and the contact upper edge.

For this purpose, an auxiliary insulator structure is formed between a lower edge of the substrate sleeve and a lower edge of the gate conductor structures between the substrate sleeves. The lower source/drain regions of the selection transistors are insulated from one another by the auxiliary insulator structure. Furthermore, a lower edge of the gate conductor structure can be set by means of a height of the auxiliary insulator structure. In this way, an overlap between the inner electrode and the gate conductor structure can be set or completely avoided. In an advantageous manner, a leakage current of the memory cell that is induced by the overlap is at least reduced.

According to another embodiment of the memory cell arrangement according to the invention, provision is made of a collar insulator structure, which underpins the substrate sleeves and here in each case extends as far as the capacitor dielectric. The substrate sleeve and thus a semiconductor body of the selection transistor that comprises the source/drain regions and the channel region are advantageously completely insulated from the semiconductor substrate by the collar insulator structure. A formation of parasitic vertical transistors for instance between the semiconductor substrate or the outer electrodes of the storage capacitors and the lower source/drain regions of the selection transistors is suppressed.

The gate conductor structures of selection transistors that are adjacent within one of the memory cell rows are in each case arranged such that they at least adjoin one another, and form, along the memory cell rows the address lines (word lines) for addressing the memory cells. Preferably, a distance between the memory cells that are adjacent within a memory cell row is provided such that the gate conductor structures of selection transistors that are in each case adjacent within a memory cell row overlap.

The distance between channel regions or substrate sleeves that are in each case adjacent to one another within the memory cell rows is particularly preferably chosen such that it corresponds to a gate conductor thickness d with which the gate conductor structures envelop the substrate sleeves.

A period distance s (pitch) designates a distance at which a structure recurs within a memory cell row, that is to say for instance the distance between the center points of two hole trenches that are adjacent within a memory cell row. Particularly preferably, mutually adjacent memory cell rows are in each case arranged offset relative to one another by half the period distances. This results in an advantageously high memory cell density particularly in the case of hole trenches having circular or elliptical cross sections. Within a memory cell row, the period distance s is preferably approximately twice a minimum feature size F with a deviation of ±10%.

As already explained, a termination of the substrate sleeves that is oriented with respect to the substrate surface is in each case formed in sections by a section of the channel region and the upper source/drain region. Arranged above the upper source/drain region is a data line contact structure which connects the upper source/drain region with an overlying data line (bit line) for the purpose of communicating the data content of the memory cell. A body contact conductor structure bears on the sections of the substrate sleeves that are formed by the channel regions, and conductively connects the channel regions of the selection transistors of memory cells that are grouped to form a memory cell array. The body contact conductor structure advantageously enables a charge carrier transport between the channel regions of the selection transistors of the memory cell array. So-called floating body effects that impair the functionality of the memory cells are thus advantageously avoided.

The data line contact structures of selection transistors that are adjacent orthogonally to the memory cell rows are arranged along a data line that is orthogonal to the memory cell row. For a maximum of permissible manufacturing tolerances, in particular of an offset between a hole trench mask for the definition of the hole trenches and a contact hole mask for the production of contact holes for the data line contact structures, the contact holes for the data line contact structures are preferably arranged on the one hand centrally between internal and external diameters of the substrate sleeve and on the other hand offset relative to the row axis. In this case, the offset relative to the row axis respectively changes sign in the case of memory cells that are adjacent to one another within a memory cell row. The magnitude of the offset is dependent on the cross-sectional form of the substrate sleeve or the hole trenches.

In a first embodiment of the memory cell arrangement according to the invention, the hole trenches or the substrate sleeves are provided with a circular cross section and can thus be arranged in a maximum density.

According to a second embodiment of the memory cell arrangement according to the invention, the hole trenches and the substrate sleeves are in each case provided with an elliptical cross section, preferably with a length-to-width ratio of 2:1. In this way, a so-called folded bit line wiring of the data lines can be embodied in a simple manner, in the case of which a connection of two adjacent memory cells to the same data line and interference effects accompanying this are avoided.

In the case of the memory cell arrangement according to the invention, the channel regions of the selection transistors are largely shielded against stray fields by the gate conductor structures. Furthermore, the channel regions of the selection transistors are connected to one another by the body contact structure. This prevents an accumulation of charge carriers in the channel region (fully depleted device). This results in a small leakage current of the memory cell. The memory cells have no overlap between the inner electrode of the storage capacitor and the gate conductor structures and thus a further reduced leakage current of the storage capacitor and also a small drain/gate capacitance of the selection transistor.

The memory cell arrangement according to the invention can be fabricated with a significantly reduced process complexity in comparison with other memory cell arrangements.

In the case of the method according to the invention for fabricating vertical memory cells formed in a semiconductor substrate with in each case a storage capacitor for storing a charge that is characteristic of a data content of the memory cell and a selection transistor for addressing the storage capacitor, in an initially known manner, hole trenches are introduced into the semiconductor substrate from a substrate surface. In a lower region below a contact lower edge of a contact structure, the hole trenches are lined with a dielectric layer as capacitor dielectric. Afterward, the hole trenches are filled with a conductive electrode material in the lower region and furthermore as far as a contact upper edge of the contact structure. In this case, an inner electrode of the storage capacitor is formed by the conductive electrode material below the contact lower edge, an outer electrode formed as a doped region in the semiconductor substrate in each case being opposite to said inner electrode at the capacitor dielectric. The contact structure adjoining the inner electrode is formed by the electrode material between the contact upper edge and the contact lower edge, which contact structure in each case electrically conductively adjoins a lower source/drain region formed in adjacent sections of the semiconductor substrate of the assigned selection transistor. A plurality of the memory cells are in each case arranged along a row axis to form memory cell rows.

According to one embodiment of the invention, the lower source/drain regions of the selection transistors are now in each case provided with sections that are contiguous and opposite to one another on the row axis at the hole trench. Thus, sections of that source/drain region which is unambiguously assigned to the selection transistor of the memory cell are exclusively formed in the semiconductor substrate adjoining the contact structure of a memory cell.

The lower source/drain regions are here in each case provided such that they envelop the respectively assigned hole trench in the region of the contact structure.

The lower source/drain regions that at least partially envelop the hole trenches preferably emerge from a spacer etching, as a result of which they are unambiguously assigned to a memory cell, on the one hand, and are electrically insulated from one another, on the other hand. For this purpose, after the filling of the lower region of the hole trenches with the electrode material, the hole trenches are in each case filled above the filling or the contact upper edge with an auxiliary material that in each case forms a conductive structure in the upper region of the hole trenches. A spacer mask with sections that are separate from one another and in each case envelop the conductive structures in an upper section is consequently produced. In the sections not covered by the spacer mask, the semiconductor substrate is caused to recede at least as far as a lower edge of the lower source/drain regions. Substrate sleeves made of the material of the semiconductor substrate are formed in the process, said substrate sleeves enveloping the hole trenches in each case above the lower edge of the lower source/drain regions. A gate dielectric and gate conductor structures are provided in each case at least in sections at the outer wall of the substrate sleeves that is in each case opposite to the conductive structure. An upper source/drain region is formed by doping in a section of a termination of the substrate sleeves that is oriented in each case with respect to the substrate surface.

The spacer mask with sections that in each case envelop the conductive structures is produced by a protective layer that is applied to the semiconductor substrate prior to the introduction of the hole trenches, for instance a pad nitride, being removed, after the forming of the conductive structures, at least from a memory cell array formed by the memory cells. As a result, the conductive structures are freed in an upper section and project above the substrate surface. As a result of a mask material that forms the spacer mask being deposited conformally and caused to recede isotropically, sections made of the mask material, for instance silicon nitride, are then produced which envelop the conductive structures in the upper section.

Prior to the formation of the gate conductor structures, provision is made of an auxiliary insulator structure, which fills the interspace between the substrate sleeves essentially between the lower edge of the substrate sleeves and the upper edge of the inner electrode or the contact lower edge. The provision of the auxiliary insulator structure prevents an overlap between the inner electrode and the gate conductor structure in a simple manner. The gate conductor structures, for their part, emerge from conformal deposition and subsequent anisotropic etching-back of a gate conductor material. In this case, they are provided in such a way that gate conductor structures assigned in each case to memory cells that are adjacent within a memory cell row adjoin one another or overlap. As a result, address lines (word lines) are formed at the same time in a simple manner, said lines connecting together the gate conductor structures or gate electrodes of selection transistors of memory cells that are adjacent in each case in rows.

Interspaces between the gate conductor structures or the address lines are filled by deposition of an insulator material. The insulator material is caused to recede by a removal as far as the substrate surface. A body contact conductor is applied to the planarized substrate surface. Body contacts to the channel regions formed in the substrate sleeves are formed by outdiffusion from the body contact conductor.

A body contact structure is patterned through a hole mask. In this case, contact holes assigned to a substrate sleeve or a memory cell in each case are produced and, in this case, an underlying section of an upper termination of the substrate sleeve is in each case uncovered. Through the contact holes, the sections of the substrate sleeves that are uncovered underneath are doped and the upper source/drain regions are thus formed. Afterward, conductive data line contact structures are provided in the contact holes, and connect the upper source/drain regions in each case to data lines running orthogonally to the address lines.

The deposition of the body contact conductor is effected in the course of a deposition of a gate conductor for p-channel field-effect transistors which are formed outside a memory cell region formed by the memory cells.

According to a first embodiment of the method according to the invention, the lower source/drain regions are formed by outdiffusion from the conductive electrode material of the inner electrode.

According to a second embodiment of the method according to the invention, the formation of the lower source/drain regions is effected in the course of an epitaxial growth of a section of the semiconductor substrate above the contact lower edge.

According to a third embodiment of the method according to the invention, the lower source/drain regions emerge from an initially unpatterned, doped lower source/drain layer.

In this case, the silicon at the outer area of the substrate sleeves is oxidized after the formation of the substrate sleeves as far as the lower edge of the lower source/drain regions. The substrate sleeves are thereby protected against a subsequent etching step in the course of which the substrate sleeves are essentially completely undercut at their lower end. The lower terminations of the substrate sleeves are in each case insulated from the semiconductor substrate by means of a subsequent filling with an insulator material.

For this purpose, an SiO₂— or SiOC-containing gel, for instance, is applied, which fills the structure and from which the SiO₂ condenses. As an alternative, silicon oxide may be deposited under conditions which lead to a preferred growth of the silicon oxide on silicon and thus enable the structure to be filled from below in a directional manner free of defect locations. The complete isolation of the selection transistor from the semiconductor substrate prevents the formation of parasitic transistor structures, for instance between the lower source/drain regions and the outer electrodes of the storage capacitors.

Finally, according to a further embodiment of the method according to the invention, the hole trenches, in the course of the deposition of the conductive electrode material, are firstly filled completely with the conductive electrode material and then the conductive electrode material is briefly etched back. Afterward, the hole trenches are filled with a dielectric that forms modified conductive structures. In this case, the conductive structures are provided in modified form as a dielectric cover having a relatively small thickness, which in each case covers a polysilicon filling of the hole trenches. The dielectric cover may subsequently advantageously be removed by means of a short CMP process, thereby uncovering the polysilicon filling. The polysilicon filling is then caused to recede, together with a dielectric layer forming the capacitor dielectric, in a defined manner as far as the contact upper edge in a simple manner.

Below the contact upper edge, a symmetrical contact window is formed between the inner electrode and the lower source/drain region. For this purpose, the dielectric layer that forms the capacitor dielectric in a region between the inner electrode and the outer electrode may be caused to recede selectively with respect to the polysilicon filling. The resulting divots between the polysilicon filling and the semiconductor substrate are filled with polysilicon.

In order to form the divots it may be necessary to provide the dielectric layer in the region of the contact window to be formed with a larger layer thickness than in the region in which it forms the capacitor dielectric. For this purpose, the dielectric layer may be grown above a lower edge of the contact window with a sacrificial layer that is self-patterning through directional growth from the substrate surface.

The method described has small vertical process tolerances, so that junctions between the structures formed within the hole trenches and the structures that have emerged from the semiconductor substrate enclosing the hole trenches can be aligned relative to one another with a small manufacturing tolerance. Furthermore, the need to provide a collar structure at the inner wall of the hole trenches is obviated. The invention is explained in more detail below with reference to the figures, identical reference symbols being used for mutually corresponding reference symbols and components

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a diagrammatic longitudinal section through and a simplified plan view of a cell array along a cell row with cell transistors having a lower source/drain region formed by a buried strap diffusion region according to a first prior art.

FIG. 2 illustrates a diagrammatic longitudinal section through a semiconductor memory device along a cell row with a contact-connection of channel regions of cell transistors according to a second prior art.

FIG. 3 illustrates a diagrammatic longitudinal section through a semiconductor memory device according to the invention in accordance with a first exemplary embodiment along a cell row.

FIG. 4 illustrates a diagrammatic cross section through the semiconductor memory device according to the invention as illustrated in FIG. 3 transversely with respect to the cell rows.

FIG. 5 illustrates a diagrammatic cross section through the semiconductor memory device according to the invention as illustrated in FIG. 3 and FIG. 4 parallel to the substrate surface.

FIG. 6 illustrates a diagrammatic plan view of the semiconductor memory device according to the invention as illustrated in FIG. 3 and FIG. 4.

FIGS. 7A-7B illustrate diagrammatic cross sections through a cell array along a cell row in two stages of a first exemplary embodiment of the method according to the invention.

FIGS. 8A-8C illustrate diagrammatic cross sections through a cell array along a cell row in three stages of a second exemplary embodiment of the method according to the invention.

FIGS. 9A-9C illustrate diagrammatic cross sections through a semiconductor memory device with a cell array and a control transistor array in three stages of a further exemplary embodiment of the method according to the invention for fabricating a semiconductor memory device.

FIG. 10 illustrates a diagrammatic cross section through a semiconductor memory device with a cell array and a control transistor array according to a further exemplary embodiment.

FIG. 11 illustrates a diagrammatic cross section through two vertical memory cells of a known type.

FIG. 12 illustrates a diagrammatic plan view of a memory cell arrangement according to the invention in accordance with a first exemplary embodiment.

FIGS. 13-18 illustrate diagrammatic cross sections through the memory cell arrangement according to the invention in accordance with the first exemplary embodiment in different process stages.

FIGS. 19-25 illustrate diagrammatic cross sections through a memory cell arrangement according to the invention in accordance with a second exemplary embodiment in different process stages.

FIG. 26 illustrates a diagrammatic plan view of the memory cell arrangement according to the invention in accordance with the first exemplary embodiment in a second sectional plane.

FIG. 27 illustrates a diagrammatic plan view of a memory cell arrangement according to the invention in accordance with a third exemplary embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,”“bottom,”“front,”“back,”“leading,”“trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

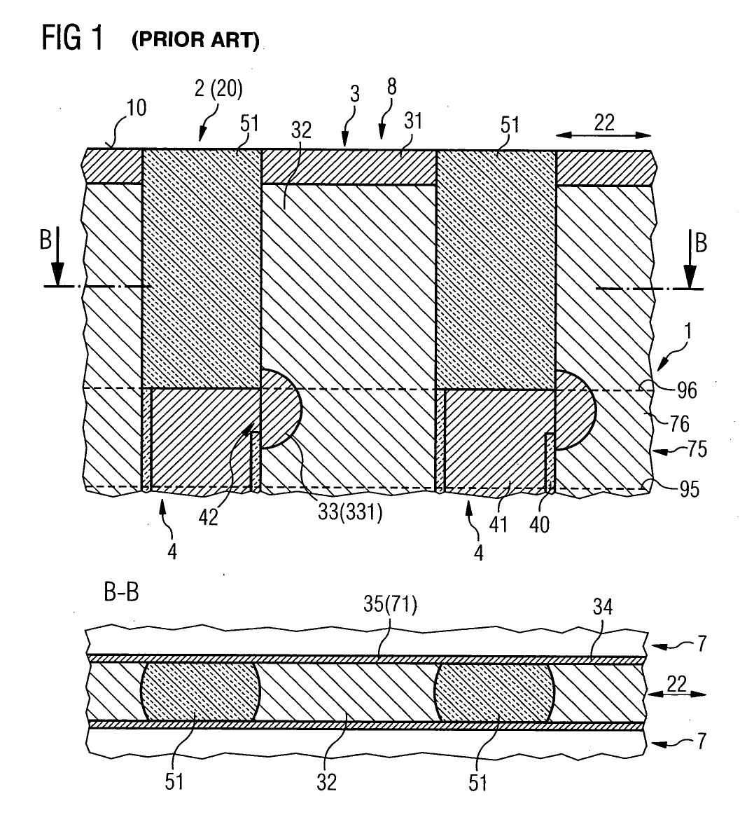

FIG. 1 illustrates a cell array of a DRAM having vertical memory cells 2. The memory cells 2 are in each case oriented to hole trenches 20 introduced into a semiconductor substrate 1 from a substrate surface 10. A cell capacitor 4 of the memory cell 2 comprises an outer electrode, which is formed as a doped region in a section of the semiconductor substrate 1 outside the region illustrated which envelops the hole trench 2 in a lower region. The outer electrodes of the cell capacitors are connected to one another and connected to a common reference potential. In the lower region, an inner electrode 41 is arranged within the hole trench 2. The inner electrode 41 is insulated outside the illustrated region by a capacitor dielectric from the outer electrode and above the outer electrode by a sidewall insulator 40 from sections of the semiconductor substrate 1 enveloping the inner electrode 41 above the outer electrode. The sidewall insulator 40 is caused to recede asymmetrically in the region of a contact window 42. The contact window 42 is adjoined by a buried strap diffusion region 331, which is n-doped in the semiconductor substrate 1 and functionally forms a lower source/drain region 33 of the cell transistor 3. An upper source/drain region 31 of the cell transistor 3 is formed as a section of an n-doped layer perforated by the hole trenches 20 and is connected to a bit line that is to be provided above the substrate surface 10. The two source/drain regions 31, 33 are spaced apart from one another by a channel region 32. In this exemplary embodiment, the hole trench 20 is filled with an insulator structure 51 in the region of the cell transistor 3. A plurality of memory cells 2 are arranged at identical distances within a cell row 22.

Adjacent cell rows 22 are isolated from one another by word line trenches 7 introduced from the substrate surface 10. Strands of word lines 71 are arranged on sidewalls of the word line trenches 7. Two strands of word lines 71 lie opposite one another at the cell row 22, and, in the case of the cell transistor 3 being formed as a double gate transistor, are strands of the word line 71 assigned to the cell transistor 3. A gate electrode 35 is then formed as a section of the word line 71 running in two strands along the cell row 22 and is insulated from the semiconductor substrate 1 and the channel region 32 by a gate dielectric 34.

A potential at the gate electrode 35 controls the formation of a conductive channel between the two source/drain regions 31, 33 in the channel region 32. By means of the conductive channel, the inner electrode 41 of the selected cell capacitor 4 is connected to a bit line which adjoins the upper source/drain region 31 and via which an electrical charge is passed to the inner electrode 41 or via which a magnitude of a charge stored on the inner electrode 41 is determined and assessed.

The channel region 32 is connected to a connection structure 75 below the lower source/drain region 33, a suitable potential being applied to said connection structure, for its part, during operation of the cell array. For this purpose, a sufficient distance has to be provided in each case between two hole trenches 20. The distance is dimensioned such that a connecting section 76 which is formed between the lower source/drain region 33 of a first memory cell and a hole trench 20 adjacent in the cell row 22 of the adjacent memory cell 2 and through which charge carriers can be led away from the channel region 32 is pinched off neither by the lower source/drain region 33 nor by a space charge zone established around the lower source/drain region 33. The dimensions and position of the lower source/drain region 33 depend on the position and form of the contact window 42.

A significant proportion of a leakage current of the memory cell 2 is supplied by a leakage current path established in an overlap region between the buried strap diffusion region 331 and the gate electrode 35 from the inner electrode 41 to the word line 71. The overlap region also determines the magnitude of a gate/drain capacitance CGD that determines the switching time of the cell transistor. Furthermore, a high doping in the overlap region, during operation of the memory cell 2, is the cause of a locally high electric field strength which adversely influences the reliability of the memory cell 2.

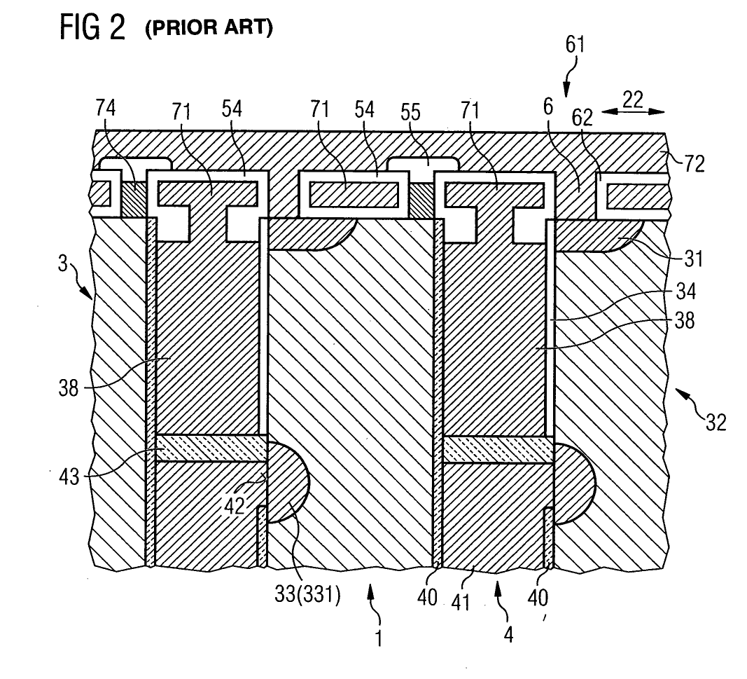

In contrast to the cell array described with reference to FIG. 1, in the case of the semiconductor memory device-illustrated in FIG. 2, the gate electrodes are arranged as trench gate electrodes 38 within the hole trenches 2 and are insulated by a capacitor termination 43 from the inner electrode 41 of the cell capacitor 4. The trench gate electrodes 38 are connected to word lines 71 arranged above the substrate surface 10. The gate dielectric 34 is provided on a front side between the semiconductor substrate 1 and the gate electrode 38. On the rear side opposite to the front side, an insulator structure 40 that insulates the inner electrode 41 in the upper region of the cell capacitor 4 from the semiconductor substrate 1 enveloping the hole trench 20 is drawn up on one side as far as the substrate surface 10.

Furthermore, in contrast to the cell array already described, in each case in the region between two hole trenches 20, both the upper source/drain region 31 and the channel region 32 of the cell transistor 3 adjoin the substrate surface 10. The upper source/drain region 31 is connected to a bit line 72. The channel region 32 is connected to a body connection interconnect 74. The body connection line 74 is insulated from the bit line by an insulator covering 55. The word lines 71 are insulated from one another, from the semiconductor substrate 1, from the bit line 72 and from the body connection line 74 by an insulator encapsulation 54.

The channel regions 32 of cell transistors 3 that are adjacent in a direction orthogonal to the cell row 22 are connected to one another via the body connection line respectively running between two word lines 71. The charge carriers that are led away accumulate within the relatively high-impedance body connection line, so that different conditions result for transporting away the charge carriers of memory cells 2 connected in this way, depending on the position of the memory cell 2 within the cell row 22.

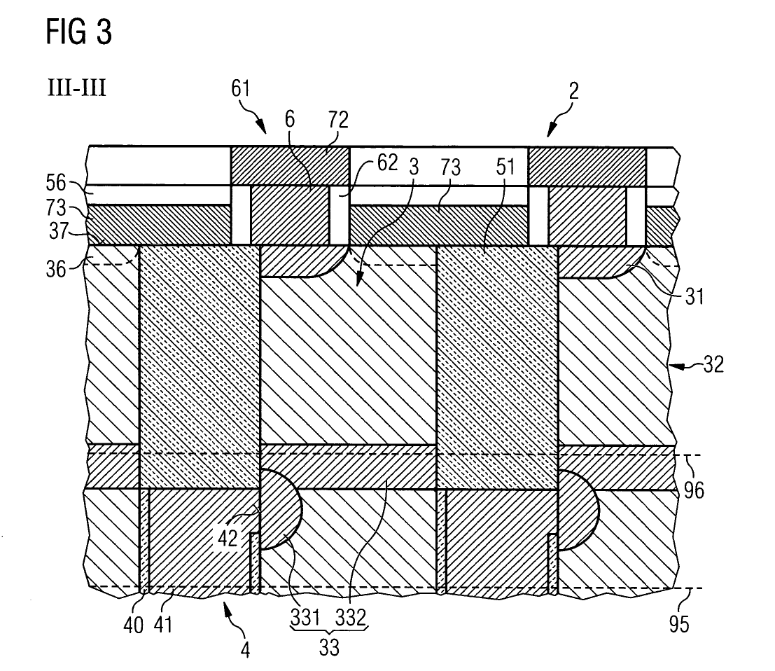

FIGS. 3-6 illustrate a semiconductor memory device according to the invention having memory cells 2.

In this case, FIG. 3 illustrates a longitudinal section through a cell row 22. In contrast to the cell array illustrated in FIG. 1 as prior art, the lower source/drain regions 33 comprise sections of a source/drain layer 332 perforated by the hole trenches 2 and the word line trenches 7. The word line trenches 7 extend between the substrate surface 10 and a lower edge 95 of the word line trenches. The source/drain layer 332 determines a doping profile, and also the position and extent of the lower source/drain region 33. Via the buried strap diffusion region 331, the lower source/drain region 33 is connected to the inner electrode 41 of the cell capacitor 4, which inner electrode is insulated from the semiconductor substrate 1 by a sidewall insulator 40 in an upper region of the cell capacitor 4.

The source/drain layer 332 makes it more difficult for the channel region 32 to be contact-connected to a section of the semiconductor substrate 1 adjoining below the lower source/drain regions 33.

Therefore, the channel region 32 is contact-connected by a body connection plate 73 bearing on the substrate surface 10 in the cell array. A nitrided interface layer 37 and/or a body contact diffusion region 36 reduces a contact resistance between the body connection plate 73 and the channel region 32. The body connection plate 73 is perforated by contact holes 61. Bit line contacts 6 insulated from the body connection plate 73 by spacer insulators 62 are provided in the contact holes 61, via which bit line contacts the upper source/drain regions are connected to the bit lines 72. In contrast to the prior art illustrated in FIG. 2, a reduced reciprocal influencing of the memory cells 2 of the cell array results by virtue of the area transporting away of the charge carriers from the channel region 32 in a plurality of directions.

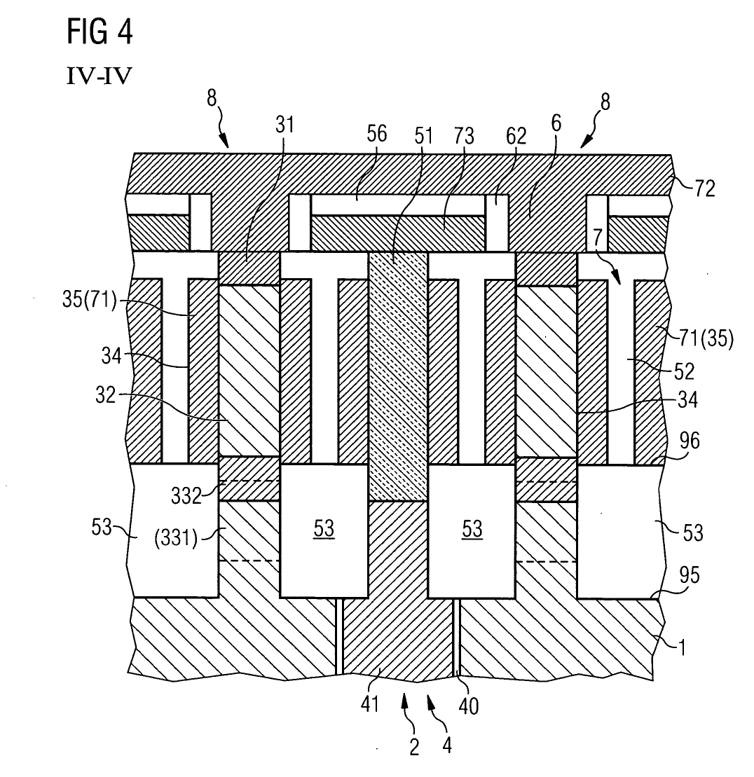

FIG. 4 illustrates a cross section transversely with respect to the cell rows 22. The cell rows 22 are isolated from one another by the word line trenches 7. The depth or a lower edge 95 of the word line trenches 7 is determined such that in particular the lower source/drain regions 33 of cell transistors 3 that are adjacent transversely with respect to the cell rows 22 are insulated from one another. The hole trenches 20 of respectively adjacent cell rows 22 are arranged offset relative to one another by in each case half the distance between the center points of the hole trenches (pitch). The cross section intersects, in the center of FIG. 4, a cell row 22 in the region of the hole trench 2 and besides that two further cell rows 22 in each case in the region of a semiconductor web 8 which is bounded by two hole trenches 2 and in which are formed the source/drain regions 31, 33 as n-doped regions and also the undoped or weakly p-doped channel region 32 of the cell transistor 3.

A respective strand of a word line 71 runs in the two word line trenches 7 bounding the cell row 22, which strand in each case forms, in sections, one of two portions of a gate electrode 35. The two portions of the gate electrode 35 enclose the channel region 32 on both sides.

A row insulator 53 is provided in a region that extends between the lower edge 95 of the word lines 71 and the lower edge 95 of the word line trenches 7, said row insulator defining a lower edge of the word lines 7 or the gate electrodes 35 relative to the upper edge of the buried strap diffusion region 331 and the source/drain layer 332.

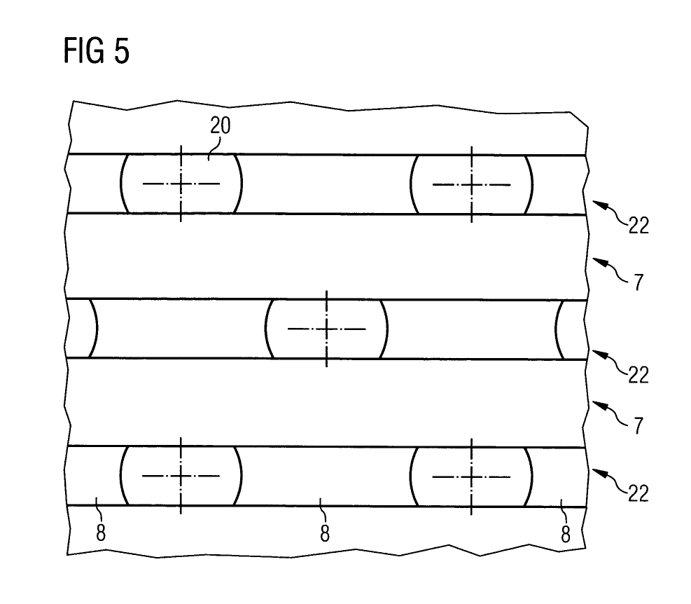

The cell array respectively illustrated in longitudinal section and cross section in FIGS. 3 and 4 is illustrated in a plan view of the substrate surface 10 in FIG. 5.

The hole trenches 20 are arranged offset relative to one another in respectively adjacent cell rows 22 by half the distance between the center points of two hole trenches 20 that are adjacent within a cell row 22. The cell rows 22 are isolated from one another by word line trenches 7. Within the cell rows 22, two hole trenches 20 in each case bound a semiconductor web 8 that forms a semiconductor body of the cell transistor 3 with the source/drain regions 31, 33 and the channel region 32.

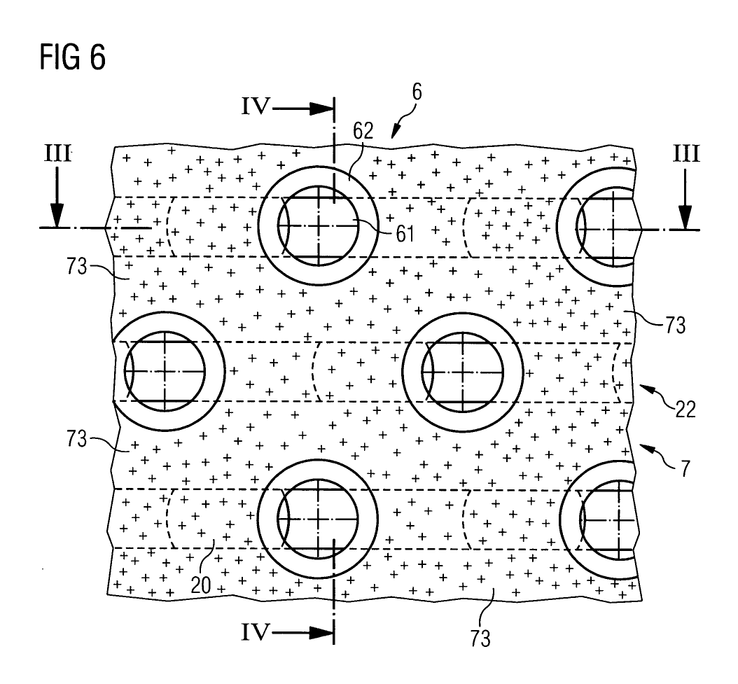

The semiconductor memory device illustrated in FIG. 6 is based on the cell array of FIG. 5, the structure of which comprising hole trenches 20 and word line trenches 7 is reproduced by broken lines. The semiconductor memory device is illustrated in a cross section parallel to the substrate surface. A body connection plate 73 perforated by contact holes 61 bears on the substrate surface. Through the contact holes 61, the upper source/drain regions 31 are formed as doped regions in the semiconductor substrate 1 by means of implantation. A bit line contact 6 insulated from the body connection plate 73 by spacer insulators 62 is in each case provided in the contact holes 61. The bit line contacts 6 connect the upper source/drain regions 31 to bit lines that are arranged above the body connection plate 73 and are insulated from the latter.

Outside the cell array, the body connection plate 73 is connected to a suitable auxiliary potential at a plurality of locations. The area formation of the body connection plate 73 makes it possible for charges to be led away from the channel regions 32 at relatively high impedance in accordance with a resistivity in the region of the intrinsic conduction of the material of the semiconductor substrate 1 and with little reciprocal influencing of the memory cells 2.

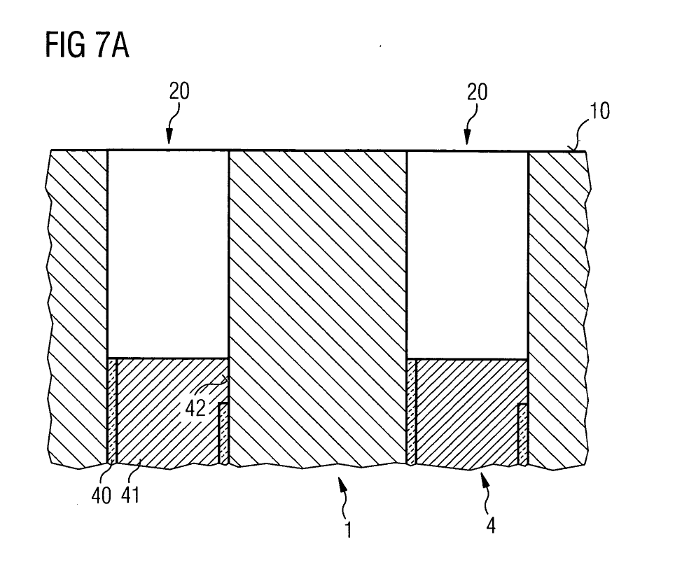

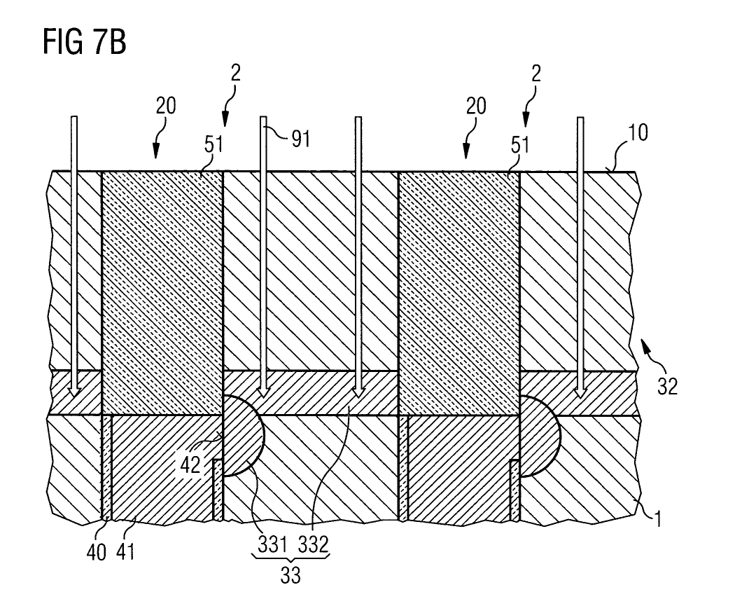

In accordance with the exemplary embodiment illustrated in the two drawings of FIG. 7, for a first exemplary embodiment of the method according to the invention, firstly a hole trench 20 is introduced into a semiconductor substrate 1 from a substrate surface 10 for each memory cell. A cell capacitor 4 with an inner electrode 41 is provided in a lower region of the hole trench 20. In the region illustrated, the inner electrode 41 is insulated by a sidewall insulator 40 from the semiconductor substrate 1 enveloping the hole trench 20. In this case, the sidewall insulator 40 is caused to recede on one side, so that the inner electrode 41 adjoins the semiconductor substrate 1 in the region of a contact window 42.

FIG. 7A illustrates two hole trenches 20 in the semiconductor substrate 1, within each of which the inner electrode 41 is provided in a lower region, which inner electrode, in the section illustrated, adjoins the semiconductor substrate 1 in the region of the contact window 42 and, outside the contact window 42, is insulated from the enveloping semiconductor substrate 1 by the sidewall insulator 40.

Afterward, a source/drain layer 332 is produced as an n-doped region by means of a deep implantation 91 in the region of the cell array. In this case, the deep implantation may comprise a plurality of implantation steps having different implantation energy in order to optimize a doping profile in the vertical direction. A buried strap diffusion region 331 is produced by outdiffusion of a dopant from the inner electrode 41 or from a temporary filling of the hole trench 20 at the place thereof, said buried strap diffusion region penetrating the source/drain layer 332 in sections.

In accordance with FIG. 7B, a respective section of the source/drain layer 331 forms the essential portion of the lower source/drain region 33 of a cell transistor 3. The lower source/drain region 33 is connected to the inner electrode 41 with low impedance by the buried strap diffusion region 331. A channel region 32 that spaces the two source/drain regions 31, 33 apart from one another may have a p-type counterdoping which contributes to the alignment of an upper edge of the source/drain layer 331.

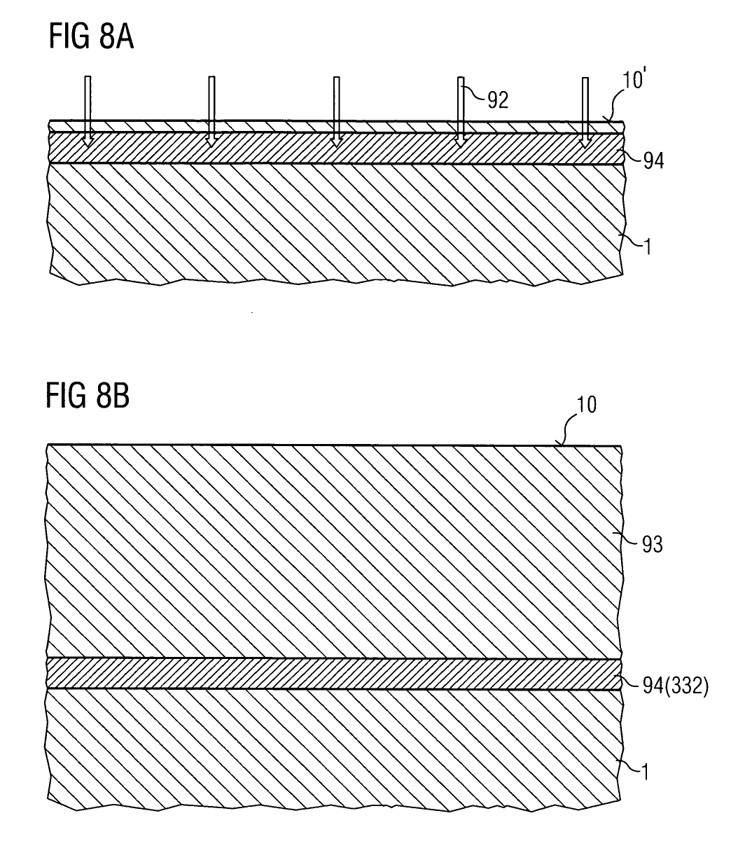

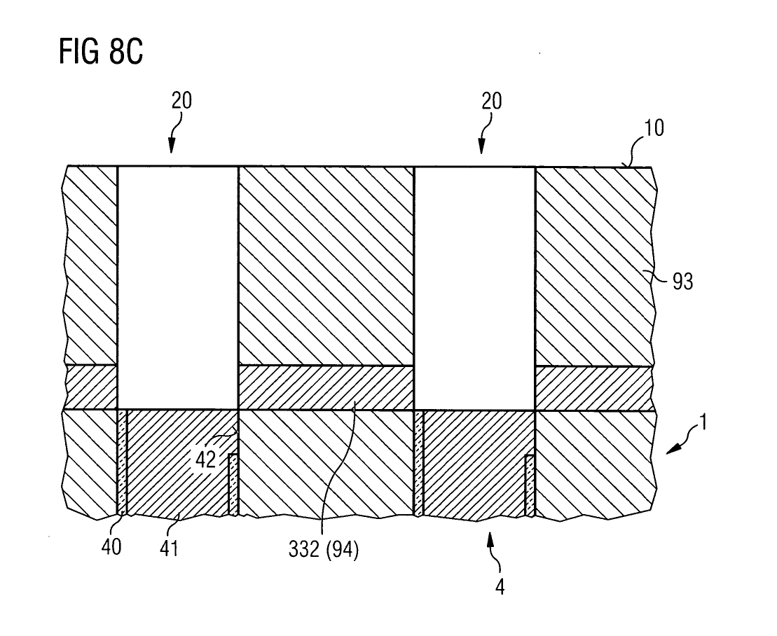

In the second embodiment for the method according to the invention as illustrated in the drawings of FIG. 8, firstly a shallow implantation 92 with low energy is performed from a provisional substrate surface 10′ in the region of the cell array.

As a result, in accordance with FIG. 8A, a precursor layer 94 is formed as an n-doped region in the semiconductor substrate 1. Semiconductor material is grown on the provisional substrate surface 10′ by means of an epitaxial method.

FIG. 8B illustrates the epitaxial layer 93 formed by the epitaxial growth. The surface of the epitaxial layer 93 forms the substrate surface 10.

Hole trenches 20 are introduced into the semiconductor substrate 1 which has the precursor layer 94 of the source/drain layer 33 in the region of the cell array. Cell capacitors 4 with an inner electrode 41 are formed in the lower region of the hole trenches 20, the inner electrode 41, in the region illustrated, being insulated by a sidewall insulator 40 from the semiconductor substrate 1 enveloping the hole trench 20. The sidewall insulator 40 is caused to recede on one side, so that the inner electrode 41 adjoins the semiconductor substrate 1 in the region of a contact window 42.

FIG. 8C illustrates the cell array in the state after the formation of the contact window 42 and prior to an outdiffusion of a dopant from the inner electrode 41 or a temporary filling at the place thereof.

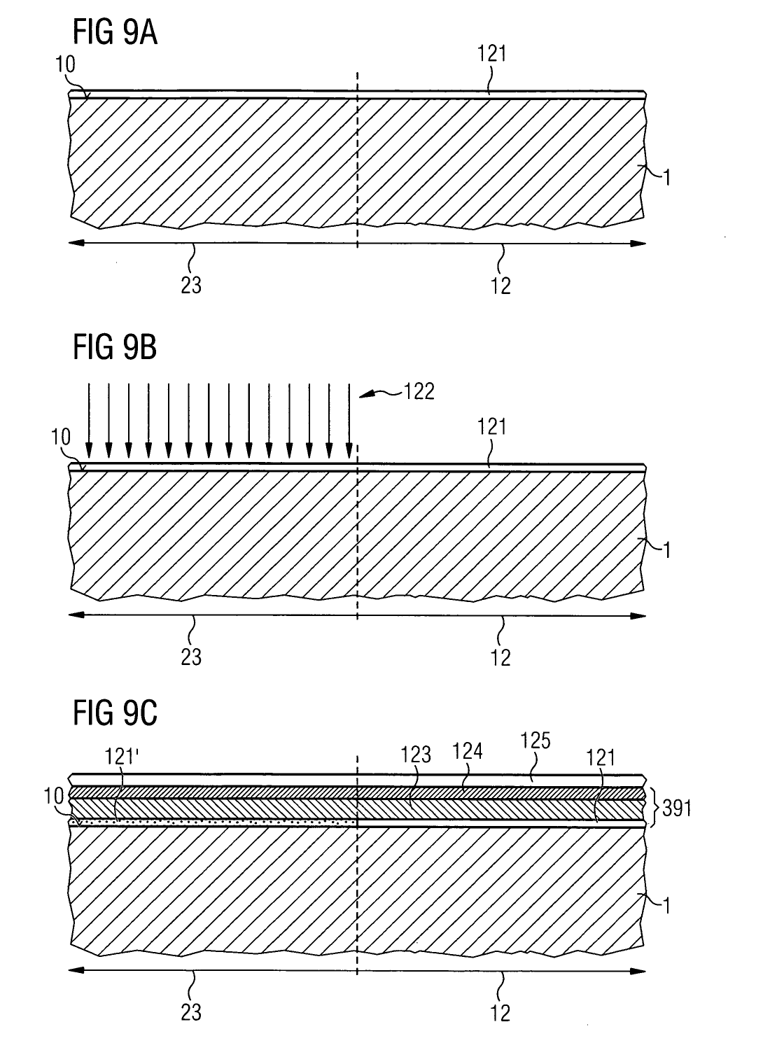

The drawings of FIG. 9 in each case illustrate a section of a cell array 23 and of a control transistor array 12 of a semiconductor memory device.

A gate dielectric layer 121 is applied or grown onto a substrate surface 10 of the semiconductor substrate 1. The material of the gate dielectric layer 121 is for example SiO₂, SiN, Al₂O₃, HfO₂, ZrO₂, TiO₂, LaO₂ or another oxide of rare earths and combinations thereof.

The semiconductor substrate 1 is shown greatly simplified in the cross section illustrated in FIG. 9A. Usually, structures for instance of hole trench capacitors, word lines and cell transistors are at least partly formed as early as prior to the provision of the gate dielectric layer 121 in the semiconductor substrate 1; said structures having been omitted from the illustration for the sake of better clarity.

In this exemplary embodiment, the gate dielectric layer 121 acquires low impedance on account of chemical conversion by means of an ion implantation 122 with germanium in the region of the cell array 23.

The ion implantation 122 acting on the gate dielectric layer 121 in the cell array 23 is illustrated in FIG. 9B.

Partial layers 123, 124 of a gate conductor layer structure 391 are applied to the gate dielectric layer 121, 121′ that has been modified in sections and an insulator layer 125 is applied to the gate conductor layer structure 391.

In the cross section illustrated in FIG. 9C, the gate conductor layer structure 391 comprises a partial layer 123 made of doped polysilicon that bears directly on the gate dielectric layer 121, 121′, which is modified in the cell array 23 and not modified in the control transistor array 12, and also a highly conductive partial layer 124 made of a metal or a metal compound. The gate conductor layer structure 391 may contain further barrier and adhesion layers as additional partial layers.

The gate conductor layer structure 391 is patterned together with the overlaying insulator layer 125 in a single photolithographic process, there being formed, from the gate conductor layer structure 391, a body connection structure 73 in the cell array 23 and gate electrode structures 393 of control transistors 39 in the control transistor array 12.

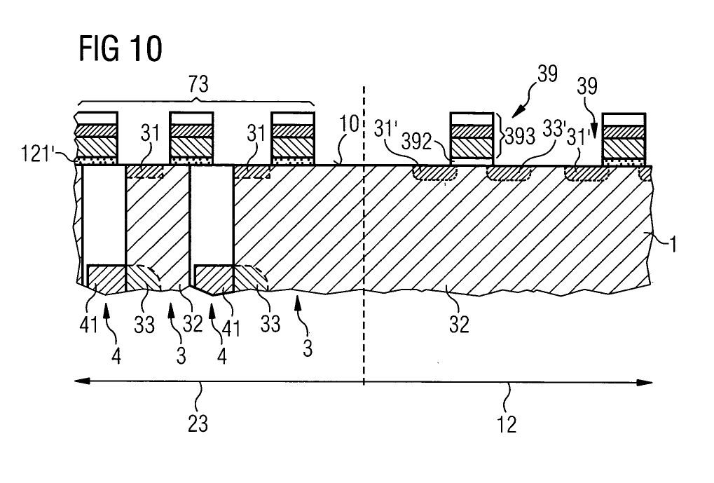

The body connection structure 73 and the gate electrode structures 393 are illustrated for a special design of the semiconductor substrate 1 in the cell array 23 in FIG. 10.

In the cell array 23, hole trench capacitors or trench capacitors 4 each having an inner electrode 41 are formed along hole trenches introduced into the semiconductor substrate 1 from the substrate surface 10. Each hole trench capacitor 4 is assigned a cell transistor 3 having two source/drain regions 31, 33 and a channel or body region 32. The lower source/drain region 33 is in each case electrically conductively connected to the inner electrode 41 of the hole trench capacitor 4. The cell transistors 33 are driven via word lines which run parallel to the cross-sectional plane essentially between the substrate surface 10 and the lower source/drain regions 33.

Planar control transistors 39 having source/drain regions 31′, 33′ formed on both sides of a respective gate electrode structure 393 in the semiconductor substrate 1 are arranged in the control transistor array 12.

Apart from the ion implantation of the gate dielectric layer 12, the body connection structure 73 emerges without additional outlay from the same gate conductor layer structure 391 as the gate electrode structures 393. Since the exposure in the cell array 23 and in the control transistor array 12 is effected using the same mask, overlay problems such as result from the alignment of a plurality of masks with respect to one another are precluded. Forming the body connection structure 73 and the gate electrode structures 393 simultaneously reduces the number of successive process steps reacting upon the respective preceding process steps. The need to provide an a really complex transition region for compensating for different step heights on the substrate surface between the cell array and the control transistor array is obviated by virtue of the identical layer thickness or step height of the gate electrode structures 393 and the body connection structure 73.

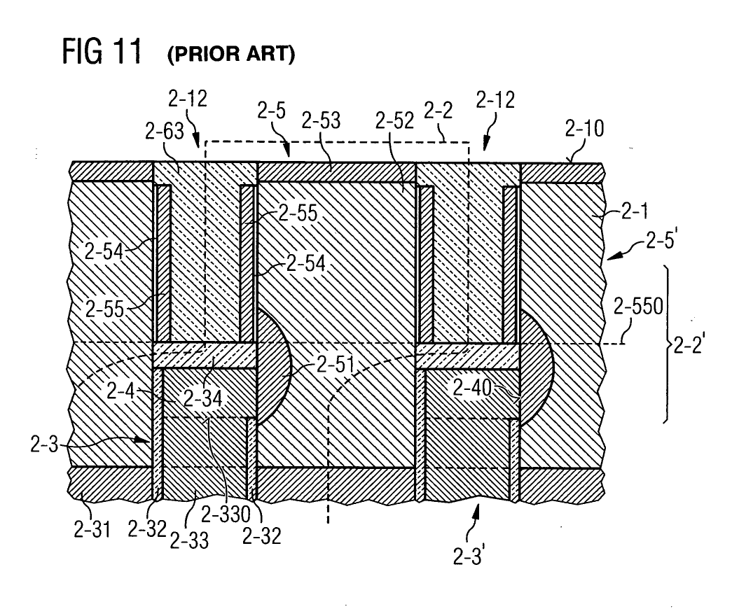

A known cell concept according to the German patent application DE 197 18 721 A1 (Roesner et al.) is illustrated in FIG. 11, which shows two memory cells 2-2 that are adjacent to one another in a memory cell row in a cross section along the memory cell row in a simplified and diagrammatic manner. In this case, the memory cells 2-2 are each assigned to hole trenches 2-12 that are introduced into a semiconductor substrate 2-1 from a substrate surface 2-10. Storage capacitors 2-3, 2-3′ are in each case formed below a capacitor termination 2-34 in lower regions of the hole trenches 2-12. An inner electrode 2-33 of the storage capacitor 2-3 is formed as a filling of the lower region made of a conductive electrode material, for instance doped polysilicon. The inner electrodes 2-33 are in each case insulated by means of a capacitor dielectric 2-32 from outer electrodes 2-31 that are in each case formed as doped regions in the semiconductor substrate 2-1. The outer electrodes 2-31 of adjacent memory cells 2-2 are conductively connected to one another. Each memory cell 2-2 is in each case assigned a selection transistor 2-5, which, in the example illustrated, is in each case formed in that region of the semiconductor substrate 2-1 which adjoins on the right of the hole trench 2-12 assigned to the memory cell 2-2. The selection transistors 2-5 in each case comprise an upper source/drain region 2-53, which is formed below the substrate surface 2-10, a lower source/drain region 2-51, which is connected to the inner electrode 2-33 of the assigned storage capacitor 2-3, and a channel region 2-52, which is arranged between the two source/drain regions 2-51, 2-53 and in which a conductive channel between the two source/drain regions 2-51, 2-53 can be controlled by a potential at a gate conductor structure 2-55 (gate conductor, GC) or gate electrode. In this case, a section of the gate conductor structure 2-55 is formed in the hole trench 2-12 above the storage capacitor 2-3. Further sections of the gate conductor structures 2-55 are formed along sidewalls of active trenches which run parallel to the memory cell rows in sectional planes parallel to the cross-sectional plane illustrated and which separate adjacent memory cell rows from one another. A gate dielectric 2-54 is provided between the gate conductor structure 2-55 and that section of the semiconductor substrate 1 which is enveloped by the gate conductor structure 2-55. In the region of a contact structure 2-4 adjoining the inner electrode 2-33, a contact area 2-40 forms a low-impedance junction between the contact structure 2-4 in the hole trench 2-12 and the lower source/drain region 2-51 formed in the semiconductor substrate 2-1. The junction is formed between the doped polysilicon of the electrode material and a monocrystalline silicon of the semiconductor substrate 2-2 and is generally subjected to a further processing for optimization with regard to the electrical resistance and stability.

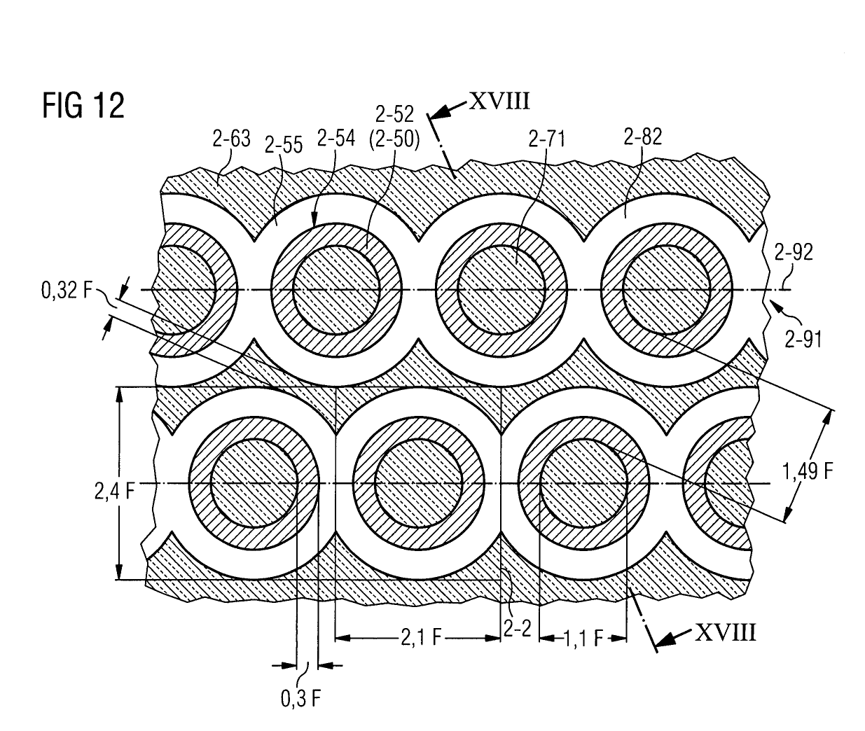

The memory cells 2-2 illustrated diagrammatically in a plan view in FIG. 12 are formed along hole trenches 2-12 having a circular cross section. In this case, the sectional plane intersects substrate sleeves 2-50 enveloping conductive structures 2-71 at a level at which a channel region 2-52 is in each case formed in the substrate sleeves 2-50. A gate dielectric 2-54 is formed in each case at least in sections at outer walls of the substrate sleeves 2-50. In a manner adjoining the gate dielectric 2-54, a gate conductor structure 2-55 in each case envelops the substrate sleeve 2-50. The gate conductor structures 2-55 of memory cells 2-2 that are in each case adjacent within a memory cell row 2-91 overlap and thereby form address lines 2-82 running along the memory cell rows 2-91. The address lines 2-82 of adjacent memory cell rows 2-91 are insulated from one another by a word line insulator 2-63. The diameter of the hole trenches 2-12 corresponds approximately to a minimum feature size F. In this exemplary embodiment, a periodicity s (pitch) with which a structure recurs within a memory cell row 2-91 is approximately 2.1 F, and a pitch of the memory cell rows 2-91 with respect to one another is approximately 2.4 F. A thickness of the substrate sleeve 2-50 and of the gate conductor structures 2-55 is approximately 0.3 F in each case. The minimum distance between two adjacent address lines 2-82 then results as approximately 0.32 F and the space requirement of a memory cell results as approximately 2.1 F times 2.4 F.

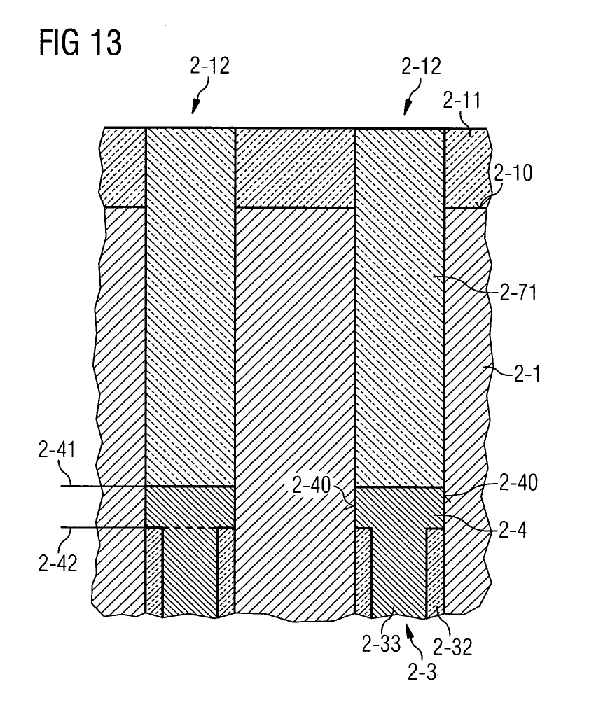

FIG. 13-FIG. 18 illustrate the method according to the invention on the basis of cross-sectional drawings through a memory cell arrangement processed in accordance with a first exemplary embodiment of the method according to the invention, in different process stages.

For this purpose, firstly a semiconductor substrate 2-1 is provided with a protective layer 2-11. Through the protective layer 2-11, hole trenches 2-12 are introduced into the semiconductor substrate 2-1. A capacitor dielectric 2-32 is arranged in a lower trench region in a known manner. The hole trenches 2-12 are filled with a conductive electrode material, for instance doped polysilicon, to above an upper edge of the capacitor dielectric 2-32. The conductive electrode material forms, in each case below a contact lower edge 2-42, an inner electrode 2-33 of a storage capacitor 2-3 assigned to a memory cell. A contact structure 2-4 is in each case shaped by means of the conductive electrode material between the contact lower edge 2-42 and a contact upper edge 2-41—determined by the height of the filling—above the contact lower edge 2-42.

FIG. 13 illustrates two hole trenches 2-12 that are introduced into a semiconductor substrate 2-1 through a protective layer 2-11. The inner electrode 2-33 of the storage capacitor 2-3, which inner electrode is insulated from the semiconductor substrate 2-1 by the capacitor dielectric 2-32, is in each case arranged in a lower region of the hole trenches 2-12. Above the inner electrode 2-33 in each case the conductive electrode material forms a contact structure 2-4, which, in this exemplary embodiment, forms a peripheral contact area 2-40 with respect to a section of the semiconductor substrate 2-1 that envelops the hole trench 2-12 at the level of the contact structure. Above the contact structure 2-4, the hole trenches 2-12 are in each case filled with a conductive structure 2-71, for instance made of silicon dioxide SiO₂.

The protective layer 2-11, usually silicon nitride, is removed selectively with respect to the material of the conductive structure 2-71. Afterward, a mask layer made of silicon nitride is deposited conformally and caused to recede anisotropically. Residual sections of the mask layer annularly envelop in each case the conductive structures 2-71 above the substrate surface 2-10 and form a spacer mask 2-13.

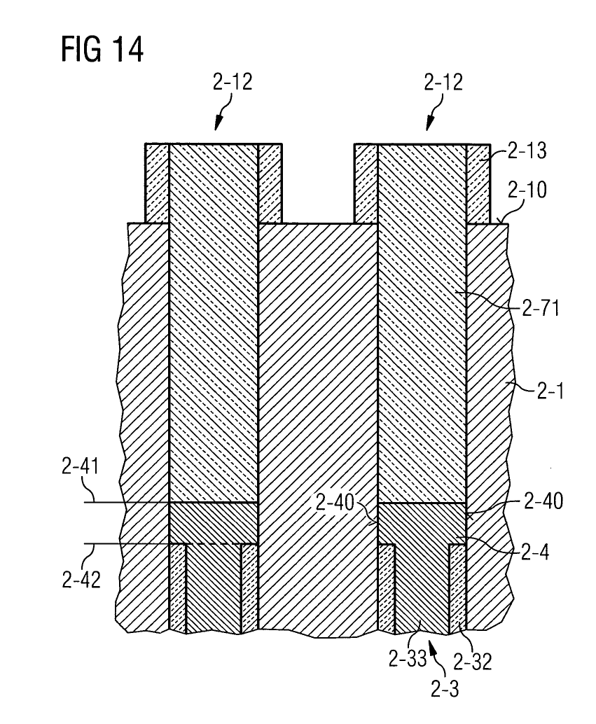

FIG. 14 illustrates the spacer mask 2-13 arranged above the substrate surface 2-10 of the semiconductor substrate 2-1.

The material of the semiconductor substrate 2-1 is subsequently etched back selectively with respect to the material of the conductive structure 2-71 and the material of the spacer mask 2-13 to an extent such that already or subsequently fashioned lower source/drain regions of adjacent memory cells are reliably isolated from one another.

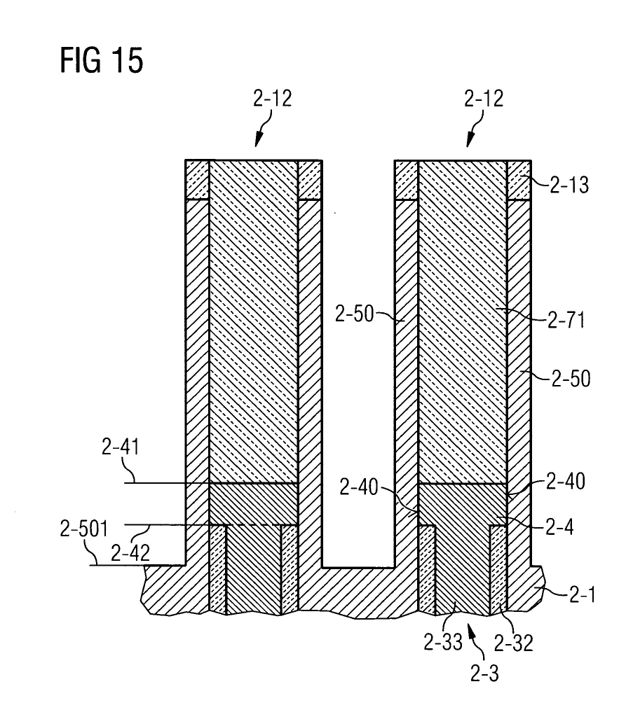

FIG. 15 reveals substrate sleeves 2-50 which have been produced by the preceding etching step and in each case envelop the conductive structures 2-71, the contact structures 2-4 and upper regions of the inner electrodes 2-33 and extend into the semiconductor substrate 2-1 as far as a lower edge 2-501.

Subsequently, firstly in a lower region, an auxiliary insulator structure 2-61 is provided in the interspace between the substrate sleeves 2-50 produced during the formation of the substrate sleeves 2-50. A gate dielectric 2-54 is either produced or applied on outer walls 2-500 of the substrate sleeves 2-50. Afterward, a gate conductor is applied conformally and etched back anisotropically to form gate conductor structures 2-55 that envelop the substrate sleeves 2-55.

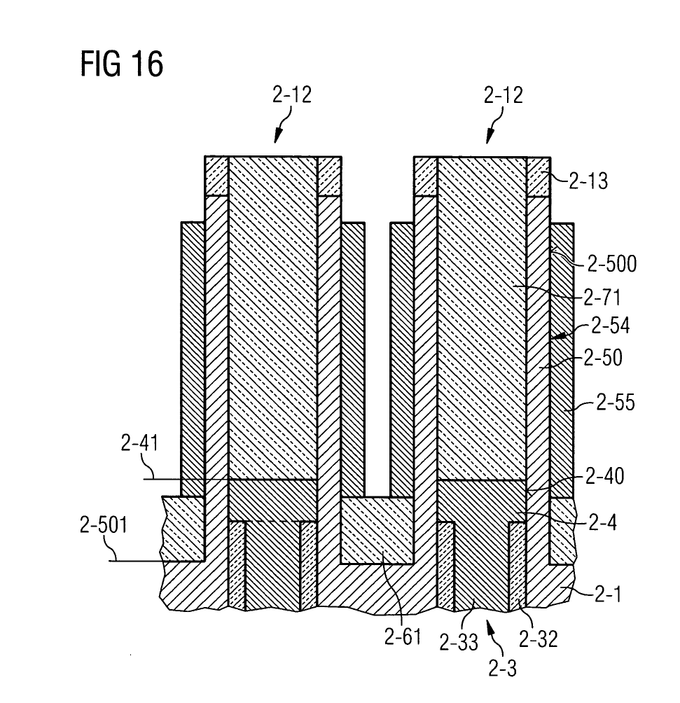

As emerges from FIG. 16, the provision of the auxiliary insulator structure 2-61 prevents an overlap between the gate conductor structure 2-55 seated thereon and the inner electrode 2-33. Such an overlap is disadvantageous since, in such an overlap region, a parasitic current path is induced between the gate conductor structure 2-55 and the inner electrode 2-33.

Afterward, interspaces remaining after the formation of the gate conductor structures 2-55 between address lines 2-82 composed of the gate conductor structures 2-55 are filled with an insulator material.

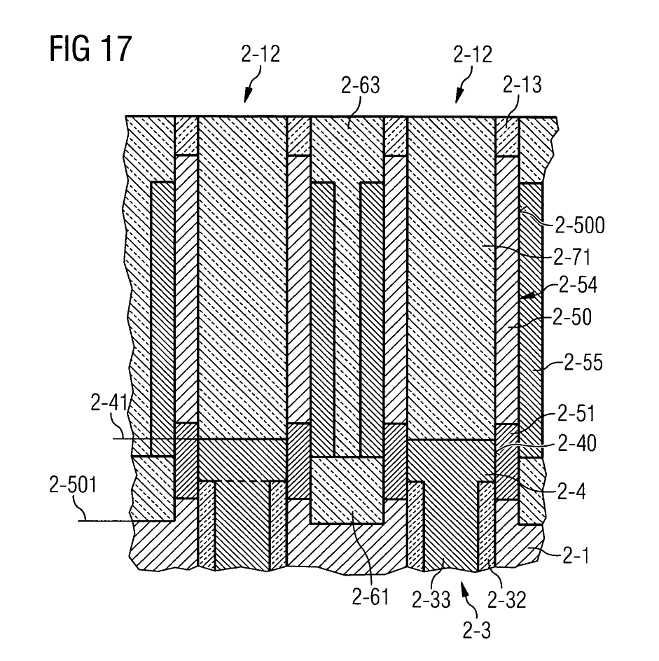

The memory cell structure thus formed with a word line insulator structure 2-63 is revealed in FIG. 17.

In addition to a memory cell array formed from the memory cells, a DRAM chip has a peripheral region in which, by way of example, an addressing logic, amplifier circuits and detection circuits are formed. A processing within the memory cell array is partly interlaced with a processing in the peripheral region. Thus, in this exemplary embodiment, the formation of the word line insulator structures 2-63 in the memory cell array is followed by a process in the course of which insulator structures are formed in the periphery (shallow trench isolation, STI). After the STI module in the periphery, the protective layer 2-11 is likewise removed there.

P-channel field-effect transistors in the periphery are provided with gate electrodes made of deposited p-doped polysilicon. The p-doped polysilicon for forming gate electrodes of p-channel field-effect transistors in the periphery is used as a body contact structure and perforated mask for implantation of the upper source/drain regions in the memory cell array. The perforated mask is patterned using a silicon dioxide hard mask. Body contacts to the channel regions are produced by means of an outdiffusion from said polysilicon. By means of a lithographic step, contact holes 2-84 are introduced into the body contact structure 2-83, said contact holes in each case uncovering an upper termination of the substrate sleeves 2-50 in sections. Afterward, the upper source/drain regions 2-53 of the selection transistors 2-5 are formed by means of an implantation through the contact holes 2-84. The contact holes 2-84 are filled with conductive material that forms data line contact structures 2-85 in the contact holes 2-84. The data line contact structures 2-85 connect the upper source/drain regions 2-53 to data lines 2-81 running above the body contact structure 2-83 orthogonally to the memory cell rows 2-91.

By means of outdiffusion from the electrode material in the region of the contact structure 2-4, lower source/drain regions 2-51 are formed in the region of the lower terminations of the substrate sleeves 2-50 in the course of the method according to the invention.

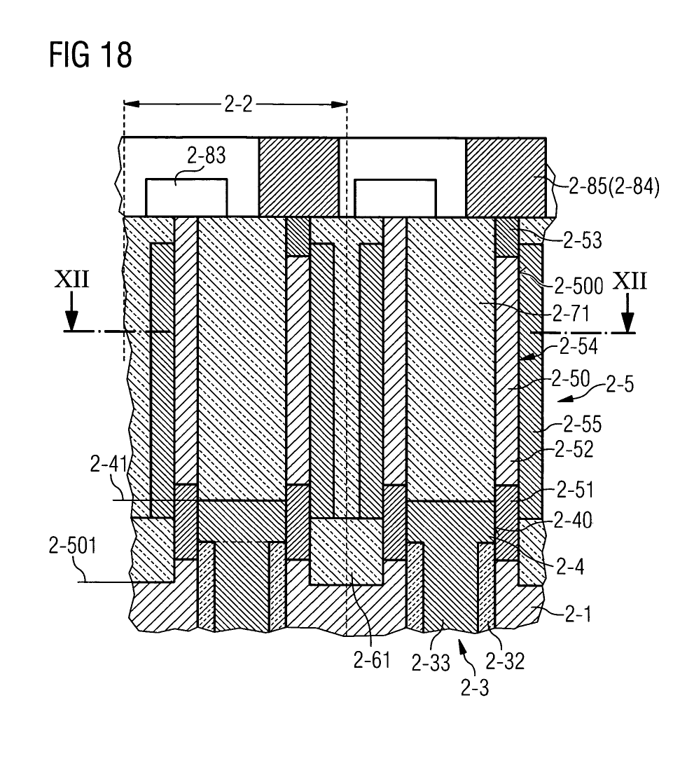

FIG. 18 illustrates a simplified diagrammatic illustration of a memory cell arrangement fabricated in this way in a memory cell array. The memory cells 2-2 each comprise a selection transistor 2-5 and a storage capacitor 2-3. The storage capacitor 2-3 is in each case formed in a lower region of a hole trench 2-12. The lower region of the hole trench 2-12 is lined with a capacitor dielectric 2-32. The capacitor dielectric 2-32 insulates an outer electrode, formed as a doped region in the semiconductor substrate 2-1, from an inner electrode 2-33. The inner electrode 2-33 and a contact structure 2-4 form sections of a filling—formed from a conductive electrode material—of the lower region of the hole trench 2-12. The contact structure 2-4 adjoins the inner electrode 2-33 above the latter and adjoins a lower source/drain region 2-51 of the selection transistor 2-5 directly with contact areas 2-40. The lower source/drain region 2-51, a channel region 2-52 and the upper source/drain region 2-53 of the selection transistor 2-5 are formed in a substrate sleeve 2-50 that envelops the hole trench 2-12 in the upper region and an upper section of the lower region. A gate dielectric 2-54 is provided at least in sections at the outer wall 2-500 of the substrate sleeve 2-50. The substrate sleeve 2-50 is enveloped by a gate conductor structure 2-55. The upper source/drain region 2-53 is formed only in sections in an upper termination of the substrate sleeve 2-50. As a result, besides the upper source/drain region 2-53, the channel region 2-52 can also be contact-connected from a substrate surface 2-10. In this case, a body contact structure 2-83 is provided a really in the region of the memory cell array on the process area 2-10′ formed in sections by the material of the substrate sleeve 2-50, the material of the word line insulator structure 2-63 and the material of the conductive structure. Data line contact structures 2-85 for connecting the upper source/drain regions 2-53 to overlying data lines are formed in contact holes 2-84 that are introduced into the body contact structure 2-83 and are insulated from the latter.

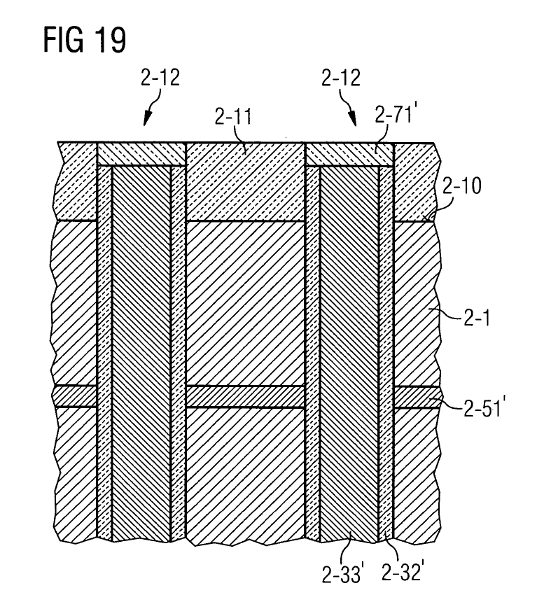

FIG. 19-FIG. 25 illustrate an exemplary embodiment of the method according to the invention in different process steps. The differences from the exemplary embodiment already described emerge during the formation of the lower source/drain regions 2-51, during the formation of the conductive structure 2-71, through the forming of a collar insulator structure 2-62 underpinning the substrate sleeve 2-50, and also in the manner in which the contact structures 2-4 are formed.

In this exemplary embodiment, firstly a buried, doped lower source/drain layer 2-51′ is produced in the semiconductor substrate 2-1, the lower source/drain regions 2-51 of selection transistors 2-5 being formed from said source/drain layer in the further course of the method. Afterward, hole trenches 2-12 are introduced into a semiconductor substrate 2-1 covered by a protective layer 2-11. The hole trenches 2-12 are lined with a capacitor dielectric 2-32 and filled with a conductive electrode material in a manner analogous to methods known for planar memory cells. In this case, in order to be able to be illustrated better the capacitor dielectric is depicted with a significantly larger layer thickness than corresponds to the actual conditions. In contrast to the method already described, the capacitor dielectric 2-32 and the material of the inner electrode 2-33 are etched back only to a small extent, for instance within the region of the protective layer 2-11, and terminated with a dielectric, for instance silicon dioxide, as modified conductive structure 2-71′.

FIG. 19 reveals the buried, doped lower source/drain layer 2-51′. It can furthermore be seen that, unlike the conductive structures 2-71 in the exemplary embodiment described above, the modified conductive structures 2-71′ do not fill the complete upper region of the hole trench 2-12, but rather only terminate a filling of the upper region.

In a manner already described, the protective layer 2-11 is then removed at least in the region of the memory cell array and a spacer mask 2-13 is formed. The semiconductor substrate 2-1 is caused to recede selectively with respect to the material of the spacer mask 2-13 initially approximately as far as a lower edge of the buried doped source/drain layer 2-51′. In this case, the lower source/drain layer 2-51′ gives rise to source/drain regions 2-51 that are separated from one another and are in each case unambiguously assigned to a storage capacitor 2-3. Afterward, an outer wall 2-500 of a substrate sleeve 2-50 produced by the etching process, which envelops the hole trench 2-12 in an upper region, is encapsulated with a protective oxide 2-56.

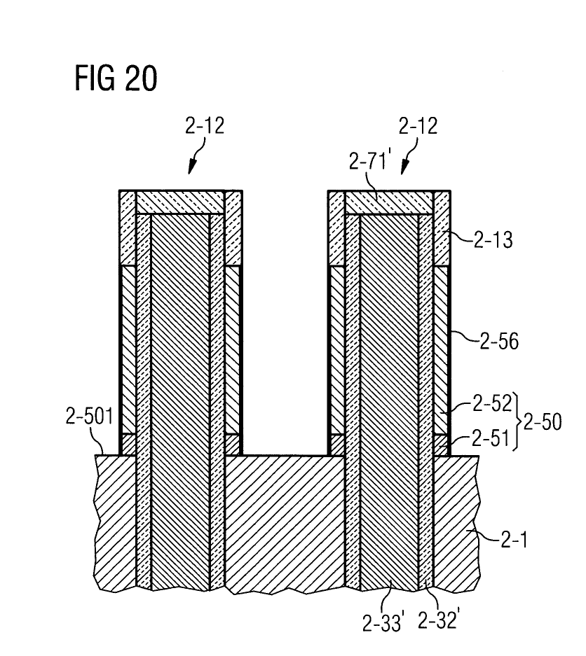

FIG. 20 illustrates the protective oxide 2-56 that protects the outer walls 2-500 of the substrate sleeves 2-50 against the next etching step.

Afterward, the semiconductor substrate 2-1 is caused to recede further below the substrate sleeve 2-50. In this case, the substrate sleeves 2-50 are undercut as far as the capacitor dielectric 2-32 or the preliminary stage thereof.

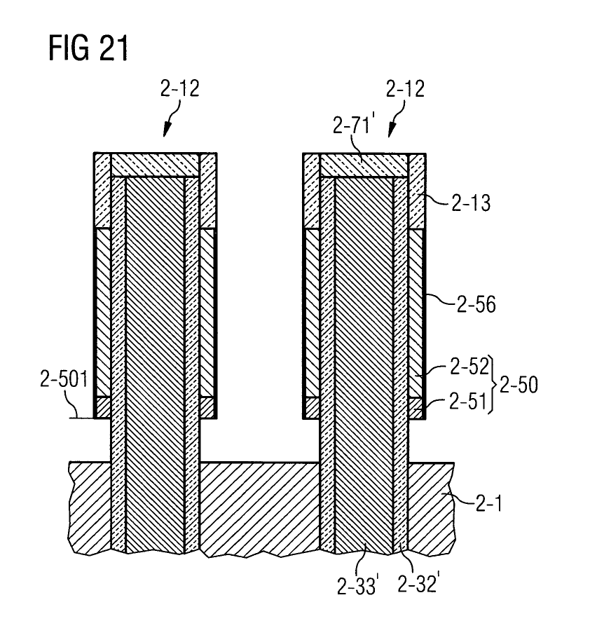

FIG. 21 illustrates the state of the memory cells after the substrate sleeves 2-50 have been undercut.

A collar insulator structure 2-62 is provided in the lower region of the interspace that separates the substrate sleeves 2-50. Afterward, the gate dielectric 2-54 and the gate conductor structures 2-55 are produced in a manner analogous to the method already described.

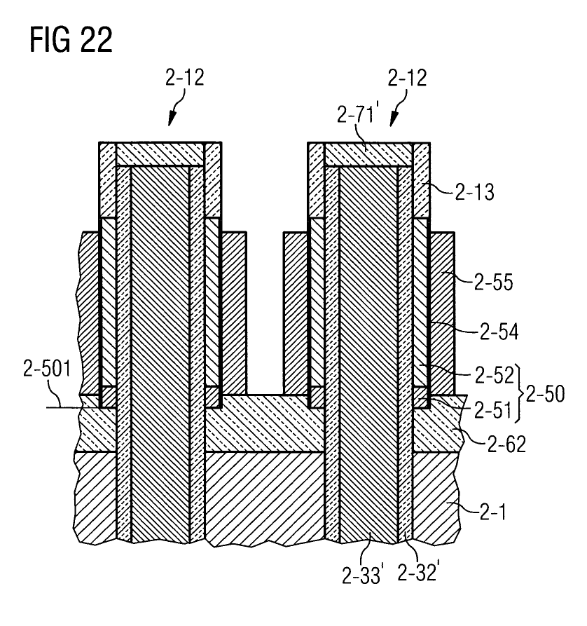

FIG. 22 reveals, in particular, that, by means of the collar insulator structure 2-62, the lower source/drain regions 2-51 are insulated not only from one another but also from the semiconductor substrate 2-1.

The subsequent process steps relate to the formation of a junction or contact window between the inner electrodes 2-33 of the storage capacitor 2-3 and the lower source/drain regions 2-51 of the selection transistors.

For this purpose, after the provision of word line insulator structures 2-63, the modified conductive structures 2-71′ and sections of the spacer mask 2-13 are caused to recede by means of a chemical mechanical polishing method (CMP) to an extent such that the conductive electrode material of the inner electrodes 2-33′ is uncovered. The electrode material of the inner electrode 2-33′ and the capacitor dielectric 2-32′ are caused to recede approximately as far as an upper edge of the lower source/drain regions 2-51.

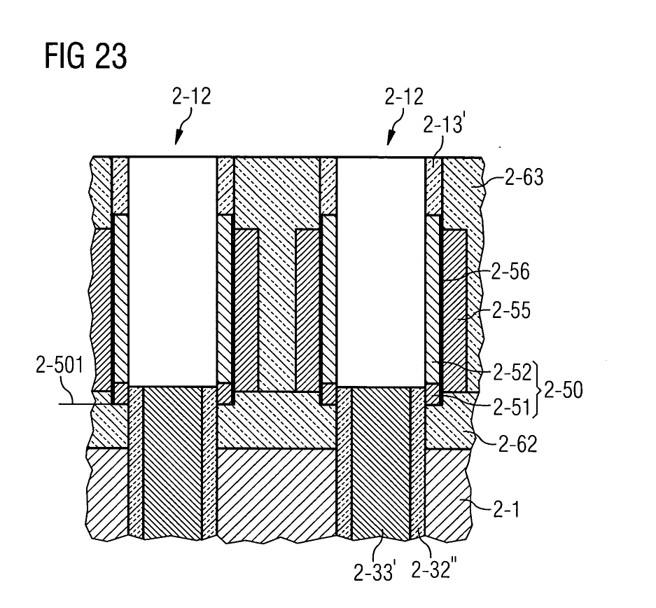

FIG. 23 illustrates the state of the processed memory cells after the preliminary stages of capacitor dielectric 2-32′ and inner electrode 2-33′ have been caused to recede as far as the lower source/drain regions 2-51.

Afterward, in this example, the capacitor dielectric 2-32, which is provided, as required, with a greater layer thickness in this region than in the region of the storage capacitor, is etched back selectively with respect to the conductive electrode material and then divots produced in the process between the lower source/drain region 2-51 and the inner electrode 2-33 are filled with a conductive material, for instance the electrode material. A nitriding may optionally be controlled at contact areas 2-40 between the contact structures 2-4 formed from the electrode material and the lower source/drain regions 2-51.

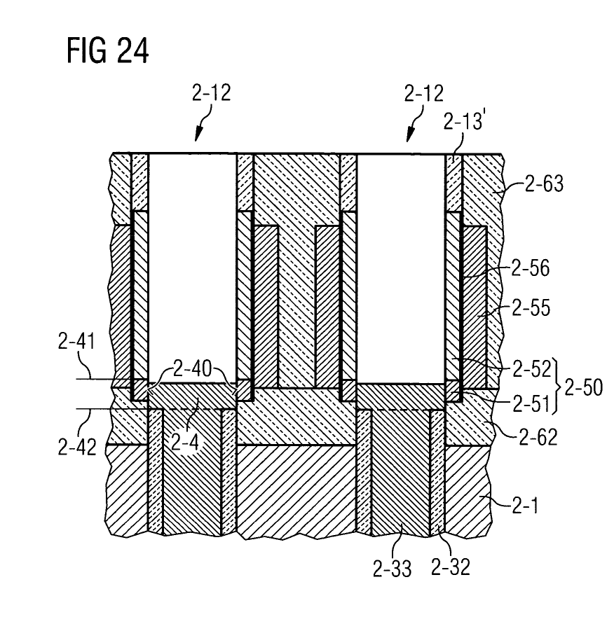

The arrangement of the contact structure 2-4 with respect to the lower source/drain region 2-51 enveloping it can be seen from FIG. 24.

The inner side of the substrate sleeve 2-50 is oxidized and the interior of the substrate sleeves 2-50 is filled with a filling structure 2-72 made of a dielectric, for example silicon dioxide. The upper source/drain regions 2-53 and also body contacts 2-83 and data line contact structures 2-85 are formed in the manner already described above.

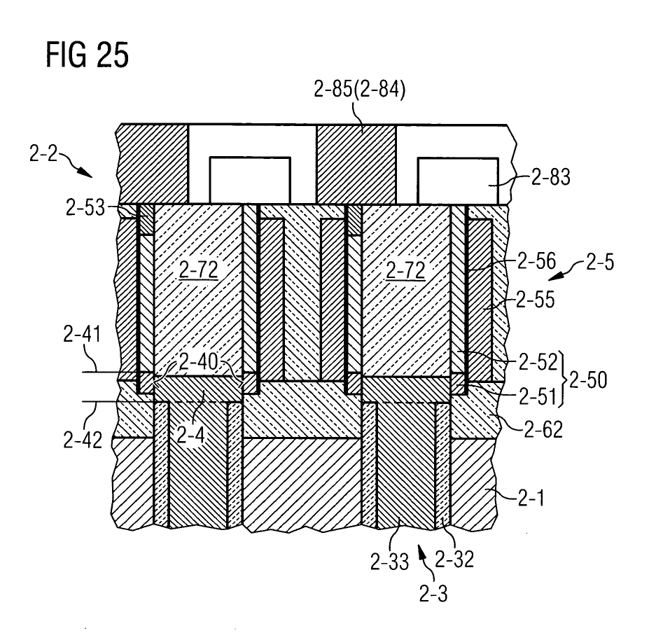

FIG. 25 represents the memory cell arrangement processed in accordance with the second exemplary embodiment of the method according to the invention in a state corresponding to FIG. 18.

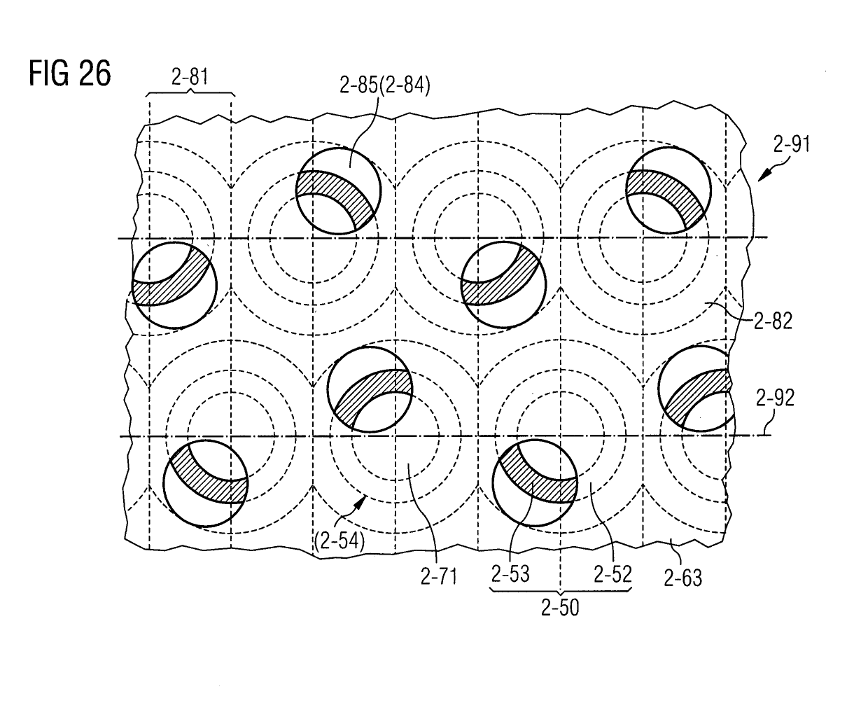

FIG. 26 illustrates a plan view of the arrangement illustrated in FIG. 12 in a section parallel to the surface, after the introduction of contact holes 2-84 into a body contact structure 2-83 applied over the area.

Contours of substrate sleeves 2-50 and of the gate conductor structures that envelop the substrate sleeves 2-50 and are arranged to form address lines 2-82 are illustrated as concealed edges. The substrate sleeves 2-50 are arranged along a row axis 2-92 in memory cell rows 2-91. Through the contact holes 2-84, upper source/drain regions 2-53 are formed in the region of the upper terminations of the substrate sleeves 2-50 by means of implantation. Under the sections of the upper terminations of the substrate sleeves 2-50 that are covered by the body contact structure 2-83, channel regions 2-52 adjoin the body contact structure 2-83. The channel regions 2-52 of selection transistors of the memory cells 2-2 arranged in the memory cell array are connected to one another via the body contact structure 2-83.

The contact holes 2-84 are filled with data line contact structures 2-85 that impart an electrical connection between the upper source/drain regions 2-53 and data lines 2-81 bearing on the body contact structure 2-83.

The position and diameter of the contact holes 2-84 are determined according to a permissible offset of a photolithographic mask that defines the contact holes 2-84 with respect to a photolithographic mask that defines the hole trenches 2-12 and also the simplest possible linking of the data line contact structures 2-85 to the data lines 2-81.

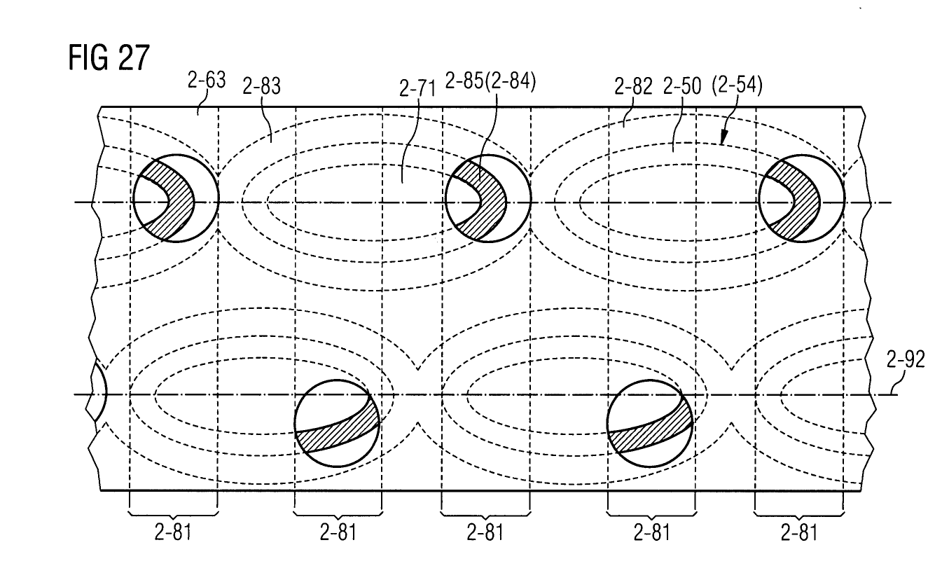

FIG. 27 illustrates a further memory cell arrangement, in which the hole trenches and consequently the substrate sleeves 2-50 are formed with an elliptical cross section, in contrast to the memory cell arrangement illustrated in FIG. 26. The elliptical cross section enables a folded bit line wiring of the memory cells in a simple manner. A folded bit line wiring prevents memory cells that are adjacent along a direction orthogonal to the memory cell row from being connected to the same data line and from reciprocally influencing one another in a disadvantageous manner.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A cell array comprising:
memory cells arranged in a semiconductor substrate to form cell rows and each having a cell capacitor for storing an electrical charge that characterizes a data content of the memory cell;
a cell transistor for selection of the memory cell;
word line trenches arranged between the cell rows;
the cell capacitor being provided in a lower region of a hole trench (20) introduced from a substrate surface of the semiconductor substrate with an inner electrode arranged in the hole trench; and
the cell transistor being formed along an upper region of the hole trench in the semiconductor substrate and having an upper source/drain region, which adjoins the substrate surface and is near the surface, a lower source/drain region, which is connected to the inner electrode of the cell capacitor, and also a channel region, which separates the two source/drain regions from one another and is insulated by a gate dielectric from a gate electrode provided in the word line trenches;
wherein the lower source/drain regions of the memory cells comprise sections of a buried source/drain layer perforated by the hole trenches and the word line trenches.

2. The cell array of claim 1, wherein the source/drain regions are formed as doped regions of a first conductivity type and a doping profile of the buried source/drain layer parallel to the substrate surface is essentially uniform.

3. The cell array of claims 1, wherein the channel regions and the upper source/drain regions of the cell transistors are formed in an epitaxially grown layer of the semiconductor substrate.

4. The cell array of claim 3, wherein a section of the buried source/drain layer is formed in the epitaxially grown layer of the semiconductor substrate.

5. The cell array of claim 1, further including buried strap diffusion regions which in each case adjoin the inner electrode in the region of a contact window, are formed as doped regions of the first conductivity type in the semiconductor substrate and penetrate the buried source/drain layer in sections.

6. The cell array of claim 5, wherein an upper edge of the lower source/drain region is formed by an upper edge of the buried source/drain layer.

7. The cell array of claim 1, wherein the gate electrodes of memory cells that are adjacent within a cell row are connected to form word lines running along the word line trenches and a lower edge of the word lines is provided above an upper edge of the buried strap diffusion regions and below the upper edge of the buried source/drain layer.

8. The cell array of claim 1, wherein the channel region has a counterdoping of a second conductivity type opposite to the first conductivity type.

9. The cell array of claim 1, wherein the channel regions of the cell transistors are provided in a manner adjoining the substrate surface in sections and are connected to a conductive body connection structure formed above the substrate surface.

10. A semiconductor memory device comprising:
a cell array, memory cells, cell transistors, and a body region, which in each case is formed in a semiconductor substrate, spaced apart a first and a second source/drain region from one another and adjoins a substrate surface of the semiconductor substrate;
a control transistor array having control transistors for controlling the cell array, gate electrode structures of the control transistors being arranged above the substrate surface; and
a body connection structure that bears on the substrate surface in the region of the cell array and is electrically conductively connected to the body regions adjoining the substrate surface in sections.

11. The semiconductor memory device of claim 10, wherein the memory cells are formed in each case in the region of a hole trench introduced into a semiconductor substrate from a substrate surface and have in each case a cell capacitor formed in a lower region of the hole trench with an inner electrode provided in the hole trench, and a cell transistor formed between the substrate surface and the lower region along the hole trench in the semiconductor substrate with an upper source/drain region, which adjoins the substrate surface and is connected to a bit line and is near the surface as the first source/drain region, and also a lower source/drain region, which is connected to the inner electrode of the cell capacitor as the second source/drain region.

12. The semiconductor memory device of claim 10, wherein the body connection structure is formed as a body connection plate that covers the cell array, bears on the substrate surface and is perforated by electrically insulated contact holes for the connection of the upper source/drain regions to the bit lines.

13. The semiconductor memory device of claim 10, wherein the body connection structure is provided from polysilicon and has a doping of a second conductivity type opposite to a first conductivity type of the source/drain regions.

14. The semiconductor memory device of claim 10, featuring body contact diffusion regions formed as doped regions of the second conductivity type in sections of the body regions adjoining the substrate surface.

15. The semiconductor memory device of claim 10, further including a nitrided boundary layer between the body regions and the body connection structure.

16. The semiconductor memory device of claim 10, wherein the body connection structure and the gate electrode structures have the same layer construction.

17. The semiconductor memory device of claim 10, wherein the body connection structure and the gate electrode structures in each case have the same layer thickness.

18. A method for fabricating a cell array having memory cells arranged in cell rows in a semiconductor substrate, in which the memory cells are provided with in each case a cell capacitor for storing an electrical charge that characterizes a data content of the memory cell and a cell transistor for selection of the memory cell comprising:
introducing hole trenches being introduced into the semiconductor substrate from a substrate surface;
forming in each case in a lower section of the hole trenches, the cell capacitor with an inner electrode within the hole trench, an outer electrode outside the hole trench and a capacitor dielectric,
forming in each case in a manner oriented to an upper section of the hole trenches, the cell transistor with a lower source/drain region adjoining the inner electrode in the semiconductor substrate, an upper source/drain region adjoining the substrate surface in the semiconductor substrate, and a channel region, which separates the source/drain regions and is insulated by a gate dielectric from a gate electrode;
providing the gate electrodes in each case provided at least partially as a section of a word line, formed in word line trenches provided between the cell rows; and
forming the lower source/drain region as a buried source/drain layer perforated by the hole trenches and the word line trenches.

19. The method of claim 18, wherein the buried source/drain layer is formed by a deep ion implantation in the region of the cell array with a dopant of a first conductivity type.

20. The method of claim 18, wherein an ion implantation with a dopant of a second conductivity type opposite to the first conductivity type is performed in a layer forming the channel regions in the cell array.

21. The method of claim 19, wherein the buried source/drain layer is formed by a shallow ion implantation in the region of the cell array and sections of the semiconductor substrate are grown epitaxially above the buried source/drain layer.

22. The method of claim 18, wherein a contact window is formed to the cell capacitor, in the region of which contact window the inner electrode adjoins the semiconductor substrate, and a dopant of the first conductivity type is outdiffused from the interior of the hole trench, a buried strap diffusion region which adjoins the inner electrode and at least partially penetrates the buried source/drain layer being formed in the semiconductor substrate.

23. A method for fabricating a semiconductor memory device having memory cells each having a cell capacitor for storing electrical charge in accordance with a data content of the memory cell and a cell transistor for addressing the memory cell, comprising:
introducing hole trenches arranged to form cell rows from a substrate surface into a semiconductor substrate;
forming the cell capacitor in a manner oriented to a lower section of the hole trench;
forming the cell transistor in the semiconductor substrate in a manner oriented to an upper section of the hole trench with a lower source/drain region connected to one of the electrodes of the cell capacitor, an upper source/drain region adjoining the substrate surface, and a channel region, which separates the two source/drain regions and adjoins the substrate surface;
connecting the upper source/drain region to a bit line and connecting the channel region to a substrate connection;
applying a body connection plate on the substrate surface prior to the formation of the upper source/drain regions;
introducing contact holes into the body connection plate that are electrically insulated from the body connection plate by spacer insulators; and
forming the upper source/drain regions by means of an implantation with a dopant corresponding to the conductivity type of the upper source/drain regions in sections of the semiconductor substrate adjoining below the contact holes.

24. The method of claim 23, wherein a nitrided boundary layer is in each case formed between the channel regions and the body connection plate.

25. The method of claim 23, wherein doped polysilicon is provided as the material of the body connection plate and a body contact diffusion region is formed by outdiffusion from the material of the body connection plate in the section of the channel region that adjoins the body connection plate below the substrate surface.

26. A method for fabricating a semiconductor memory device, comprising:
providing, in a cell array of the semiconductor memory device, cell transistors having in each case a body region that is formed in a semiconductor substrate, spaces apart a first and a second source/drain region from one another and adjoins a substrate surface;
providing a gate dielectric layer on the substrate surface of the semiconductor substrate in a control transistor array of the semiconductor memory device;
applying a gate conductor layer structure applied on the gate dielectric layer;
forming gate electrode structures of control transistors patterning the gate conductor layer structure in the control transistor array; and
providing the gate dielectric layer over the whole area, and, in the cell array is subjected to a treatment that reduces the electrical resistance.

27. The method of claim 26, wherein the gate conductor layer structure is provided over the whole area on the gate dielectric layer and a body connection structure that makes contact with the body regions is formed from the gate conductor layer structure in the cell array.

28. The method of claim 26, wherein the body connection structure and the gate electrode structures are formed in the course of the same patterning step.

29. The method of claim 26, wherein the electrical resistance of the gate dielectric layer in the cell array is reduced by implantation with a dopant.

30. The method of claim 29, wherein the dopant is selected from a material group having the elements nitrogen, boron, germanium and indium.

31. The method of claim 26, wherein the semiconductor substrate is subjected to a nitridation prior to the provision of the gate dielectric layer in the cell array.

32. The method of claim 26, wherein the gate dielectric layer is caused to recede or removed in the cell array by means of a wet etching process.

33. The method of claim 26, wherein the electrical resistivity of the gate dielectric layer in the cell array is reduced by application of an electrical potential between the body connection structure and the semiconductor substrate.

34. The method of claim 26, wherein the cell array is formed in accordance with a method comprising:
introducing hole trenches being introduced into the semiconductor substrate from a substrate surface;
forming in each case in a lower section of the hole trenches, the cell capacitor with an inner electrode within the hole trench, an outer electrode outside the hole trench and a capacitor dielectric,
forming in each case in a manner oriented to an upper section of the hole trenches, the cell transistor with a lower source/drain region adjoining the inner electrode in the semiconductor substrate, an upper source/drain region adjoining the substrate surface in the semiconductor substrate, and a channel region, which separates the source/drain regions and is insulated by a gate dielectric from a gate electrode;
providing the gate electrodes in each case provided at least partially as a section of a word line, formed in word line trenches provided between the cell rows; and
forming the lower source/drain region as a buried source/drain layer perforated by the hole trenches and the word line trenches.

35. The method of claim 26, wherein a layer made of intrinsically conducting polysilicon is deposited during the application of the gate conductor layer structure.

36. The method of claim 35, wherein the layer made of intrinsically conducting polysilicon in the cell array and also the source/drain regions and the gate electrode structures of p-channel field-effect transistors in the control transistor array are doped with a dopant of the p-conductivity type in the same doping step.

37. The method of claim 26, wherein a layer made of doped polysilicon is deposited during the application of the gate conductor layer structure.

38. The method of claim 37, wherein the body connection structure is processed together with the gate electrode structures of p-channel field-effect transistors in the control transistor array.

39. The method of claim 26, wherein the gate dielectric layer is provided with a layer thickness of a maximum of 2.5 nanometers.

40. An arrangement of vertical memory cells each having a storage capacitor formed in a semiconductor substrate and a selection transistor, comprising:
the storage capacitor being in each case formed in a lower region of a hole trench, introduced into the semiconductor substrate from a substrate surface, below a contact structure;
a lower and an upper source/drain region, and also a channel region, arranged between the two source/drain regions of the selection transistor respectively assigned to the storage capacitor formed in the semiconductor substrate between the substrate surface and the contact structure;
the contact structure in each case adjoining an inner electrode arranged in the hole trench of the storage capacitor, and the lower source/drain region formed in the semiconductor substrate opposite the contact structure of the selection transistor with a contact area;
a plurality of memory cells in each case arranged along a row axis in memory cell rows; and
gate conductor structures of selection transistors arranged in the memory cell row and connected by address lines provided below the substrate surface;
wherein the lower source/drain region of the selection transistor in each case has sections that are contiguous and opposite on the row axis at the hole trench assigned to the selection transistor.

41. The memory cell arrangement of claim 40, wherein the contact structure is formed symmetrically with respect to a plane of symmetry orthogonal to the row axis to a central axis of the respective hole trench.

42. The memory cell arrangement of claim 40, wherein the lower source/drain region extends over at least 50% of a periphery of the respectively assigned hole trench.

43. The memory cell of claim 42 wherein the lower source/drain region in each case completely envelops the respectively assigned hole trench.

44. The memory cell arrangement of claim 40, wherein the channel region is suitable for forming a conductive channel that can be controlled by a potential at a gate conductor structure of the selection transistor in a direction that is essentially vertical with respect to the substrate surface.

45. The memory cell arrangement of claim 44, wherein the channel region adjoins the respectively assigned lower source/drain region in the vertical direction.

46. The memory cell arrangement of claim 44, wherein the upper source/drain region adjoins the respectively assigned channel region at least in sections in the vertical direction.

47. The memory cell arrangement of claim 44, wherein in each case the upper source/drain region, the channel region and the lower source/drain region are formed in a substrate sleeve that extends from the substrate surface at least as far as a contact lower edge of the contact structure and envelops the hole trench.

48. The memory cell arrangement of claim 47, wherein the gate conductor structures are in each case arranged along an outer wall of the substrate sleeve that is essentially opposite to the hole trench at the channel region.

49. The memory cell arrangement of claim 47, wherein the gate conductor structures are in each case provided essentially between a lower edge of the upper source/drain region and a contact upper edge of the contact structure.

50. The memory cell arrangement of claim 47, further including an auxiliary insulator structure, which is arranged between a lower edge of the substrate sleeve and the gate conductor structure and insulates the lower source/drain regions of the selection transistors from one another.

51. The memory cell arrangement of claims 47, furthering including a collar insulator structure, which is arranged in sections in the elongation of the substrate sleeves in the direction of the semiconductor substrate and in each case insulates the substrate sleeves from the semiconductor substrate.

52. The memory cell arrangement of claim 47, wherein the memory cells are arranged in a memory cell array in a plurality of memory cell rows that are arranged next to one another and oriented parallel to one another and the gate conductor structures of selection transistors that are adjacent within one of the memory cell rows are in each case arranged such that they at least adjoin one another.

53. The memory cell arrangement of claim 52, wherein the gate conductor structures of the selection transistors that are adjacent within a memory cell row are in each case provided such that they overlap one another.

54. The memory cell arrangement of claim 53, wherein a distance between substrate sleeves that are in each case adjacent to one another within the memory cell rows essentially corresponds to a gate conductor thickness with which the gate conductor structures envelop the substrate sleeves.

55. The memory cell arrangement of claim 53, wherein mutually adjacent memory cell rows are arranged offset relative to one another in each case by half of a period distance formed from a distance between the center points of two hole trenches that are adjacent within a memory cell row.

56. The memory cell arrangement of claim 47, wherein the upper source/drain region is in each case formed in a section arranged below a data line contact structure at a termination of the substrate sleeve that is oriented with respect to the substrate surface.

57. The memory cell arrangement of claim 47, wherein the termination of the substrate sleeve that is oriented with respect to the substrate surface is formed outside the upper source/drain region in each case by the channel region.

58. The memory cell arrangement of claim 57, further including a body contact structure, which bears on the channel regions of the selection transistors and connects the channel regions of the selection transistors to one another.

59. The memory cell arrangement of claim 56, wherein the data line contact structures of selection transistors that are adjacent orthogonally to the memory cell row are arranged along a data line that is orthogonal to the memory cell row.

60. The memory cell arrangement of claim 56, wherein the hole trenches are in each case formed with an essentially circular cross section.

61. The memory cell arrangement of claim 56, wherein the hole trenches are formed with an elliptical cross section and a ratio of a longitudinal axis to a transverse axis of essentially 2:1.

62. A method for fabricating vertical memory cells having selection transistors for addressing storage capacitors formed in a semiconductor substrate, comprising:
introducing hole trenches into the semiconductor substrate from a substrate surface;
lining the hole trenches in each case with a capacitor dielectric at least below a contact lower edge of a contact structure;
filling the hole trenches in each case with a conductive electrode material at least below a contact upper edge of a contact structure, in which case, consequently, an inner electrode of the storage capacitor is in each case formed below the contact lower edge and the contact structure is formed between the contact upper edge and the contact lower edge;
forming lower source/drain regions of the selection transistors in each case in sections of the semiconductor substrate that adjoin the contact structure;
arranging a plurality of the memory cells in each case along a row axis to form memory cell rows; and
providing the lower source/drain regions with sections that are contiguous with one another and mutually opposite one another on the row axis in each case at the hole trench.

63. The method of claim 62, wherein the lower source/drain regions are provided in a manner enveloping the respectively assigned hole trench.

64. The method of claim 62, wherein in the course of filling the hole trenches with the electrode material, the hole trenches are filled with the electrode material as far as the contact upper edge, a conductive structure is in each case formed in the hole trenches above the contact upper edge, a spacer mask is produced from spacer sections respectively enveloping the conductive structures, the semiconductor substrate is caused to recede in sections not covered by the spacer mask as far as a lower edge of the lower source/drain regions, substrate sleeves being formed which in each case envelop the hole trenches at least above the lower edge of the lower source/drain regions, a gate dielectric and a gate conductor structure are provided, at least in sections, at outer walls of the substrate sleeves, and an upper source/drain region is formed in an upper termination of the substrate sleeve that is oriented with respect to the substrate surface.

65. The method of claim 62, wherein prior to the introduction of the hole trenches, a protective layer is applied to the semiconductor substrate, the protective layer is removed after the formation of the conductive structures, the conductive structures in each case being freed in an upper section, sections of a spacer mask that envelop the conductive structures at least in the upper section are produced by a mask material being deposited conformally and caused to recede anistropically.

66. The method of claim 62, wherein prior to the provision of the gate conductor structures, provision is made of an auxiliary insulator structure, which fills an interspace between the substrate sleeves between a lower edge of the substrate sleeves and the contact lower edge.

67. The method of claim 62, wherein the gate conductor structures are formed by conformal deposition and subsequent anisotropic etching-back of a gate conductor.

68. The method of claim 62, wherein interspaces between adjacent gate conductor structures are filled with a word line insulator, the word line insulator is caused to recede by a removal as far as the substrate surface, word line insulator structures emerging between the gate conductor structures, a body contact conductor is applied to a planarized process area that is formed in sections by the word line insulator structures, the filling structures and the substrate sleeves.

69. The method of claim 68, wherein body contacts are formed by outdiffusion from the body contact conductor.

70. The method of claim 68, wherein a body contact structure is patterned through a perforated mask, contact holes assigned to a substrate sleeve in each case being produced and a section of an upper termination of the substrate sleeve in each case being uncovered in the process, through the contact holes, the sections of the substrate sleeves that are uncovered underneath are doped and upper source/drain regions of the selection transistors are thereby formed, and conductive data line contact structures are provided in the contact holes.

71. The method of claim 68, wherein the deposition of the body contact conductor is effected in the course of a deposition of a gate conductor for p-channel transistors outside a memory cell array formed by the memory cells.

72. The method of claim 62, wherein the lower source/drain regions are in each case formed by outdiffusion from the electrode material.

73. The method of claim 62, wherein the lower source/drain regions are formed at least in sections from a buried doped layer.
